(19) United States
(12) Patent Application Publication
(10) Pub. No.: US 2026/0215125 A1
(43) Pub. Date: Jul. 23, 2026

(54) DISPLAY DEVICE AND ELECTRONIC DEVICE INCLUDING THE SAME

(71) Applicants: SAMSUNG DISPLAY CO., LTD., YONGIN-SI (KR); University Industry Foundation, Yonsei University, Seoul (KR)

(72) Inventors: TAEWOONG KIM, Yongin-si (KR); Jong Hyun AHN, Seoul (KR); Min Jun KIM, Seoul (KR); Beom Jin KIM, Seoul (KR); Seok Min YUN, Seoul (KR)

(21) Appl. No.: 19/437,835

(22) Filed: Dec. 31, 2025

(30) Foreign Application Priority Data
Jan. 21, 2025 (KR) 10-2025-0008659

(51) Int. Cl. H10K 59/80; H10K 102/00

(52) U.S. Cl. CPC H10K 59/80; H10K 2102/311

(57) ABSTRACT

A display device includes a display module including a first non-folding area, a second non-folding area, and a folding area disposed between the first non-folding area and the second non-folding area, and a panel support including a first panel support, an auxetic structure, and a second panel support disposed below the display module and sequentially disposed in a first direction. The first panel support overlaps the first non-folding area, the second panel support overlaps the second non-folding area, and the auxetic structure overlaps the folding area. The auxetic structure includes a plurality of repeated unit patterns, the unit pattern is asymmetrical with respect to a first virtual line passing through a central point of the unit pattern, and the first virtual line is parallel to a folding axis of the folding area extending in a second direction perpendicular to the first direction.

### CROSS-REFERENCE TO RELATED APPLICATIONS

This application claims priority under 35 U.S.C. § 119 to Korean Patent Application No. 10-2025-0008659, filed on Jan. 21, 2025, the disclosure of which is incorporated by reference herein in its entirety.

### TECHNICAL FIELD

Embodiments of the present disclosure relate to a display device and an electronic device including the same.

### DISCUSSION OF RELATED ART

Electronic devices such as smartphones, tablet PCs, notebook computers, automotive navigation systems, and smart televisions have become widely adopted. These electronic devices typically include display devices for presenting visual information to users.

To improve user experience and interface (UX/UI), various types of display devices have been developed. Among them, flexible display devices have seen significant advancement. For example, flexible displays have been developed that may improve properties such as shock absorption, mechanical strength, tensile durability, and resilience, especially in folding regions.

### SUMMARY

Embodiments of the present disclosure provide a display device having improved shock absorption, strength, tension, and resilience, and an electronic device including the same.

According to an embodiment, a display device includes a first non-folding area, a second non-folding area, and a folding area disposed between the first non-folding area and the second non-folding area, and a panel support including a first panel support, an auxetic structure, and a second panel support disposed below the display module and sequentially disposed in a first direction. The first panel support overlaps the first non-folding area, the second panel support overlaps the second non-folding area, and the auxetic structure overlaps the folding area. The auxetic structure includes a plurality of repeated unit patterns, the unit pattern is asymmetrical with respect to a first virtual line passing through a central point of the unit pattern, and the first virtual line is parallel to a folding axis of the folding area extending in a second direction perpendicular to the first direction.

In an embodiment, an angle formed between a second virtual line and the first virtual line passing through the central point of the unit pattern is an acute angle, and the unit pattern is vertically symmetrical.

In an embodiment, the auxetic structure has a negative Poissons ratio.

In an embodiment, the negative Poissons ratio of the auxetic structure is about −0.3 to about 0.

In an embodiment, the display device further includes a line pattern defining the plurality of unit patterns.

In an embodiment, the line pattern has a thickness of about 30 μm to about 100 μm.

In an embodiment, the auxetic structure includes at least one of stainless steel, copper, titanium, aluminum, and high-density polyethylene (HDPE).

In an embodiment, the plurality of unit patterns disposed along the second virtual line has a pitch of about 450 μm to about 2,000 μm.

In an embodiment, the auxetic structure has a modulus of about 10 MPa to about 1 GPa.

In an embodiment, the unit pattern includes a plurality of arms spaced apart from one another at a same angle and extending from the central point of the unit pattern.

In an embodiment, the plurality of arms includes three arms.

In an embodiment, an end of one of the arms is convex with respect to the central point of the unit pattern, and a waist of the one arm between the end of the one arm and the central point of the unit pattern is concave.

In an embodiment, the one arm has a smallest angle between an extension line from the central point of the unit pattern to the one arm and the first virtual line, and an angle between a second virtual line connecting the one arm to the central point of the unit pattern and the first virtual line is about 30° or less.

In an embodiment, the panel support has a thickness of about 30 μm to about 200 μm.

In an embodiment, the display module provides a display surface, the display surface provides a flat surface in a first mode of the display device, and at least a portion of the display surface provides a curved surface on the basis of a reference axis extending in the second direction in a second mode.

According to an embodiment, a display device includes a display module including a first non-folding area, a second non-folding area, and a folding area disposed between the first non-folding area and the second non-folding area, and a panel support including a first panel support, an auxetic structure, and a second panel support disposed below the display module and sequentially disposed in a first direction. The first panel support overlaps the first non-folding area, the second panel support overlaps the second non-folding area, the auxetic structure overlaps the folding area. The auxetic structure includes a plurality of repeated unit patterns, the unit pattern includes three arms spaced apart from one another at a same angle and extending from a central point of the unit pattern, the unit pattern is asymmetrical with respect to a first virtual line passing through the central point of the unit pattern, and the first virtual line is parallel to a folding axis of the folding area extending in a second direction perpendicular to the first direction.

In an embodiment, an end of one of the arms is convex with respect to the central point of the unit pattern, and a waist of the one arm between the end of the one arm and the central point of the unit pattern is concave.

In an embodiment, the one arm includes a first arm having a smallest angle between an extension line from the central point of the unit pattern to the one arm and the first virtual line, and an angle between a second virtual line connecting the one arm to the central point of the unit pattern and the first virtual line is about 30° or less.

In an embodiment, the display device further includes a line pattern defining the plurality of unit patterns, and the line pattern has a thickness of about 30 μm to about 100 μm.

According to an embodiment, an electronic device includes a display device. The display device includes a display module including a first non-folding area, a second non-folding area, and a folding area disposed between the first non-folding area and the second non-folding area, and a panel support including a first panel support, an auxetic structure, and a second panel support disposed below the display module and sequentially disposed in a first direction. The first panel support overlaps the first non-folding area, the second panel support overlaps the second non-folding area, the auxetic structure overlaps the folding area. Theauxetic structure includes a plurality of repeated unit patterns, the unit pattern is asymmetrical with respect to a first virtual line passing through a central point of the unit pattern, and the first virtual line is parallel to a folding axis of the folding area extending in a second direction perpendicular to the first direction.

### BRIEF DESCRIPTION OF THE DRAWINGS

The above and other features of the present disclosure will become more apparent by describing in detail embodiments thereof with reference to the accompanying drawings, in which:

FIGS. 1A to 1C are perspective views of an electronic device according to an embodiment;

FIG. 2A is an exploded perspective view of an electronic device according to an embodiment;

FIG. 2B is a block diagram of an electronic device according to an embodiment;

FIG. 3A is a plan view of a display panel according to an embodiment;

FIG. 3B is a plan view of a partial area of a display panel according to an embodiment;

FIG. 4 is a cross-sectional view of an example of a display module taken along line I-I′ of FIG. 2A;

FIG. 5 is a cross-sectional view of a portion of a display module according to an embodiment;

FIG. 6 is a side view of an example of a display device taken along line II-II′ of FIG. 3A;

FIG. 7 is a plan view schematically illustrating an auxetic structure according to an embodiment;

FIG. 8 is a plan view schematically illustrating one unit pattern of FIG. 7;

FIG. 9 is a plan view schematically illustrating an auxetic structure according to an embodiment;

FIG. 10 is a plan view schematically illustrating one unit pattern of FIG. 9;

FIG. 11 is a plan view schematically illustrating an auxetic structure according to an embodiment;

FIG. 12 is a plan view schematically illustrating one unit pattern of FIG. 11;

FIG. 13 is a block diagram of an electronic device according to an embodiment; and

FIG. 14 is a view schematically illustrating various types of electronic devices according to various embodiments.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

It will be further understood that the terms “comprises,” “comprising,” “includes,” and/or “including” when used in this specification, specify a presence of stated features, integers, steps, operations, elements, and/or components, but do not preclude the presence or addition of one or more other features, integers, steps, operations, elements, components, and/or groups thereof.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ±30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

In the following embodiments, the terms such as “connect” or “combine” do not necessarily mean direct and/or fixed connection or combination of two members unless the context clearly indicates otherwise, and do not preclude another member intervening between the two members.

Embodiments of the present disclosure provide a foldable display device including a panel support structure with an auxetic region positioned in a folding area. The auxetic structure may be formed by a repeated unit pattern and may be arranged between two rigid panel supports that correspond to respective non-folding regions of the display module. This arrangement may allow the folding area to undergo localized expansion or contraction in response to mechanical deformation along a folding axis, which may support the folding motion of the display module while helping to maintain its structural integrity.

The auxetic structure according to embodiments may be configured such that its modulus and negative Poisson's ratio vary depending on its orientation relative to the folding axis. Accordingly, the mechanical response of the folding area, including its ability to stretch and return to its original shape, can differ depending on how the pattern is arranged. Certain unit patterns, including, for example, star-shaped configurations oriented at specific angles with respect to the folding axis, may offer improved deformation characteristics for use in foldable displays. By selecting and orienting the auxetic pattern appropriately, embodiments may reduce crease formation and provide reliable folding behavior.

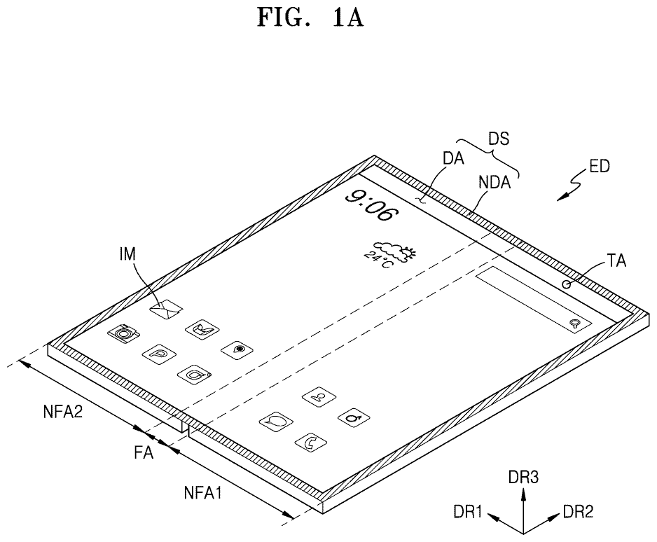

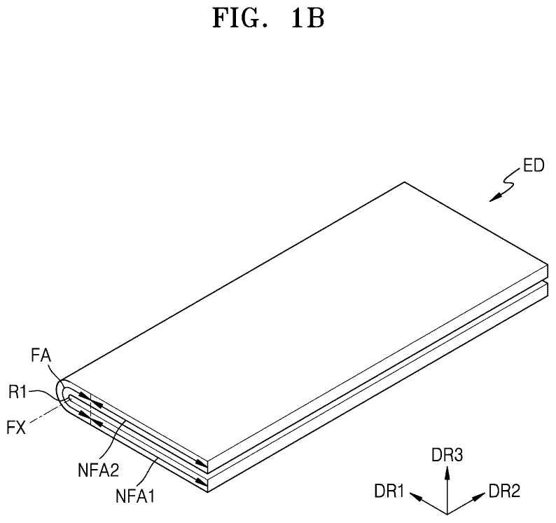

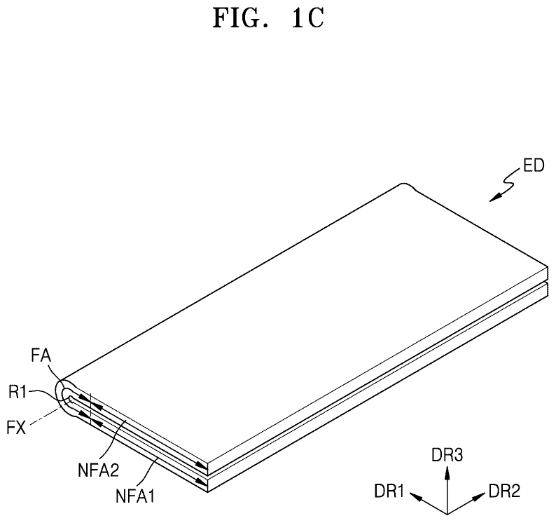

FIGS. 1A to 1C are perspective views of an electronic device according to an embodiment. FIG. 1A illustrates an unfolded state of an electronic device, and FIG. 1B and FIG. 1C illustrate a folded state of the electronic device.

Referring to FIGS. 1A to 1C, an electronic device ED according to an embodiment may include a display surface DS defined by a first direction DR1 and a second direction DR2 intersecting the first direction DR1. The electronic device ED may provide an image IM to a user through the display surface DS.

The display surface DS may include a display area DA and a non-display area NDA around the display area DA. In an embodiment, the image is displayed in the display area DA and is not displayed in the non-display area NDA. The non-display area NDA may surround the display area DA. However, the present disclosure is not limited thereto, and a shape of the display area DA and a shape of the non-display area NDA may be modified.

The display surface DS may include a sensing area TA. The sensing area TA may be a partial area of the display area DA. The sensing area TA may have a higher transmittance than the other area of the display area DA. Hereinafter, the other area of the display area DA except for the sensing area TA may be defined as a normal display area.

An optical signal, e.g., visible light or infrared light, may travel into the sensing area TA. The electronic device ED may capture an external image through visible light passing through the sensing area TA or determine accessibility of an external object through infrared light. Although FIG. 1A illustrates one sensing area TA, the present disclosure is not limited thereto, and a plurality of sensing areas TA may be provided.

Hereinafter, a direction substantially perpendicularly intersecting a plane defined by the first direction DR1 and the second direction DR2 may be defined as a third direction DR3. The third direction DR3 may operate as a reference for distinguishing a front surface and a back surface of each of units. In the present description, “on a plane” may be defined as a state viewed in the third direction DR3. For example, “on a plane” may refer to a state in which the object being referred to is viewed in a plan view. Hereinafter, the first direction, DR1, the second direction DR2, and the third direction DR3 may refer to directions indicated by a first directional axis, a second directional axis, and a third directional axis, respectively.

The electronic device ED may include a folding area FA and a plurality of non-folding areas NFA1 and NFA2. The non-folding areas NFA1 and NFA2 may include a first non-folding area NFA1 and a second non-folding area NFA2. The folding area FA may be disposed between the first non-folding area NFA1 and the second non-folding area NFA2 in the first direction DR1.

As illustrated in FIG. 1B, the folding area FA may be folded with respect to a folding axis FX extending in the second direction DR2. The folding area FA may have a certain curvature and radius of curvature R1. The first non-folding area NFA1 and the second non-folding area NFA2 may face each other, and the electronic device ED may be inner-folded so that the display surface DS is not exposed and may be protected when folded.

In an embodiment, the electronic device ED may be outer-folded so that the display surface DS is exposed when folded. For example, the display surface DS provided by a display module DM may provide a plane in a first mode of the display device DD, and at least a portion of the display surface DS may provide, in a second mode, a curved surface around the folding axis FX extending in the second direction DR2.

In an embodiment, the electronic device ED may be configured such that an inner-folding operation and an outer-folding operation are mutually repeated from an unfolding operation, but is not limited thereto. In an embodiment, the electronic device ED may be configured to select any one of the unfolding operation, the inner-folding operation, and the outer-folding operation.

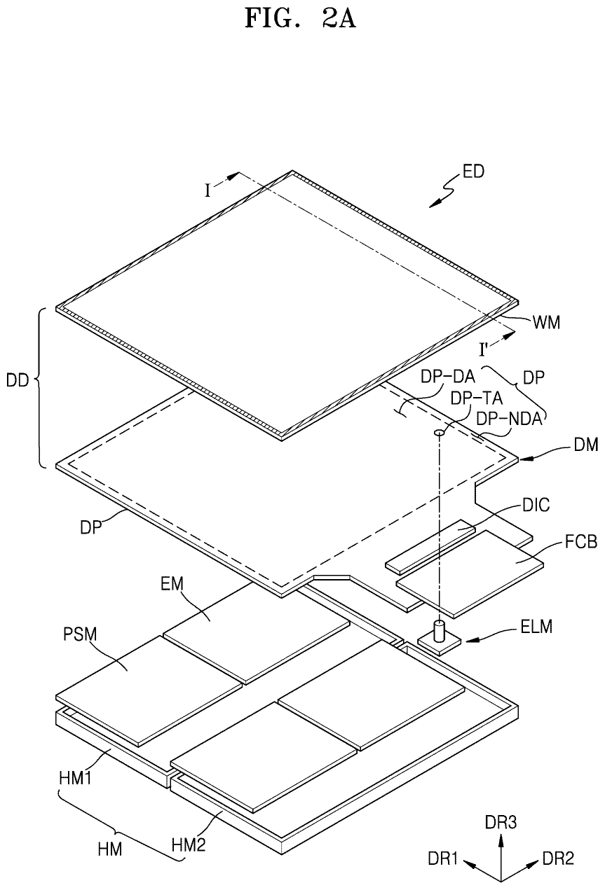

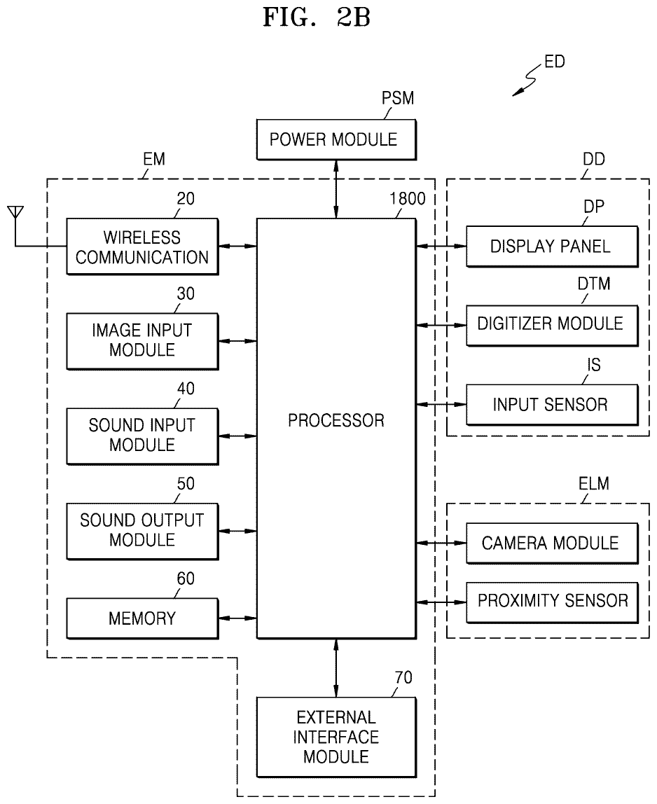

As illustrated in FIG. 1B, in an embodiment, a distance between the first non-folding area NFA1 and the second non-folding area NFA2 may be substantially the same as the radius of curvature R1. As illustrated in FIG. 1C, in an embodiment, the distance between the first non-folding area NFA1 and the second non-folding area NFA2 may be less than the radius of curvature R1. FIGS. 1B and 1C illustrate the electronic device ED on the basis of the display surface DS, and a housing HM (refer to FIG. 2A) forming the appearance of the electronic device ED may be in contact with end areas of the first non-folding area NFA1 and the second non-folding area NFA2.

FIG. 2A is an exploded perspective view of an electronic device according to an embodiment. FIG. 2B is a block diagram of an electronic device according to an embodiment.

As illustrated in FIGS. 2A and 2B, an electronic device ED may include a display device DD, an electronic module EM, an electro-optical module ELM, a power module PSM, and the housing HM. In an embodiment, the electronic device ED may further include a mechanical structure that controls a folding operation of the display device DD.

The display device DD may generate an image and detect an external input. The display device DD may include a window WM and a display module DM. The window WM may provide a front surface of the electronic device ED. A detailed description of the window WM is provided below.

The display module DM may include at least a display panel DP. Although FIG. 2A illustrates only the display panel DP from among stacked structures of the display module DM, the display module DM may further include a plurality of components disposed on the display panel DP. A detailed description of the stacked structures of the display module DM is provided below. For example, the display module DM may refer to a layered structure configured to display visual information, and may include the display panel DP, as well as one or more components such as a light-emitting layer, a polarizer, a thin film encapsulation layer, or other layers commonly used in display technologies.

The display panel DP is not particularly limited, and may be, for example, a light-emitting display panel such as an organic light-emitting display panel or a quantum dot light-emitting display panel. The display panel DP may be a display panel including an ultra-small light-emitting device such as a micro light-emitting diode (LED) or a nano LED.

The display panel DP may include a display area DP-DA and a non-display area DP-NDA corresponding to the display area DA (refer to FIG. 1A) and the non-display area NDA (refer to FIG. 1A) of the electronic device ED, respectively. In the present description, the expression “an area/portion corresponds to an area/portion” may indicate that the area/portion may overlap the area/portion and is not limited to the same area.

The display panel DP may include a sensing area DP-TA corresponding to the sensing area TA of FIG. 1A. The sensing area DP-TA may be an area having a lower resolution than the display area DP-DA. A detailed description of the sensing area DP-TA is provided below.

As illustrated in FIG. 2A, a driving chip DIC may be disposed in the non-display area DP-NDA of the display panel DP. A flexible circuit board FCB may be coupled to the non-display area DP-NDA of the display panel DP. The flexible circuit board FCB may be connected to a main circuit board. The main circuit board may include one electronic component constituting the electronic module EM.

The driving chip DIC may include driving elements that drive pixels of the display panel DP, for example, a data driving circuit. Although FIG. 2A illustrates a structure in which the driving chip DIC is mounted on the display panel DP, the present disclosure is not limited thereto. For example, the driving chip DIC may be mounted on the flexible circuit board FCB.

As illustrated in FIG. 2B, the display device DD may further include an input sensor IS and a digitizer module DTM. The input sensor IS may detect a user input. The capacitive input sensor IS may be disposed on the display panel DP. The digitizer module DTM may detect an input of a stylus pen. The electromagnetic induction type digitizer module DTM may be disposed below the display panel DP.

The electronic module EM may include a processor 1800, a wireless communication module 20, an image input module 30, a sound input module 40, a sound output module 50, a memory 60, and an external interface module 70. The electronic module EM may include the main circuit board, and modules described above may be mounted on the main circuit board or may be electrically connected to the main circuit board through the flexible circuit board FCB. The electronic module EM may be electrically connected to a power module (also referred to as a power source) PSM.

Referring to FIG. 2B, the electronic module EM may be disposed in each of a first housing HM1 and a second housing HM2 of the housing HM, and the power module PSM may be disposed in each of the first housing HM1 and the second housing HM2. The electronic module EM disposed in the first housing HM1 and the electronic module EM disposed in the second housing HM2 may be electrically connected to each other through the flexible circuit board FCB.

The processor 1800 may control the overall operation of the electronic device ED. For example, the processor 1800 may activate or deactivate the display device DD according to a user input. The processor 1800 may control the image input module 30, the sound input module 40, the sound output module 50, and the like according to the user input. The processor 1800 may include at least one microprocessor.

The wireless communication module 20 may transmit and/or receive a wireless signal to and/or from another terminal by using, for example, a BLUETOOTH or WI-FI connection. The wireless communication module 20 may transmit and/or receive a speech signal by using a normal communication line. The wireless communication module 20 may include a plurality of antenna modules.

The image input module 30 may process an image signal and convert the image signal into image data that may be displayed on the display device DD. The sound input module 40 may receive an external sound signal through a microphone in a recording mode, a speech recognition mode, or the like and convert the external sound signal into electrical speech data. The sound output module 50 may convert sound data received from the wireless communication module 20 or sound data stored in the memory 60 and output the converted sound data to the outside.

The external interface module 70 may operate as an interface connected to, for example, an external charger, a wired/wireless data port, a card socket (e.g., a memory card, a subscriber identity module (SIM)/user identity module (UIM) card, or the like), or the like.

The power module PSM may supply power used for the overall operation of the electronic device ED. The power module PSM may include a normal battery device.

The electro-optical module ELM may be an electronic component that outputs or receives an optical signal. The electro-optical module ELM may include a camera module and/or a proximity sensor. The camera module may capture an external image through the sensing area DP-TA.

The housing HM illustrated in FIG. 2A may be coupled to the display device DD, for example, the window WM, to accommodate the other modules. The housing HM may include the first housing HM1 and the second housing HM2 that are separated from each other, but is not limited thereto. The electronic device ED may further include a hinge structure that connects the first housing HM1 and the second housing HM2 to each other.

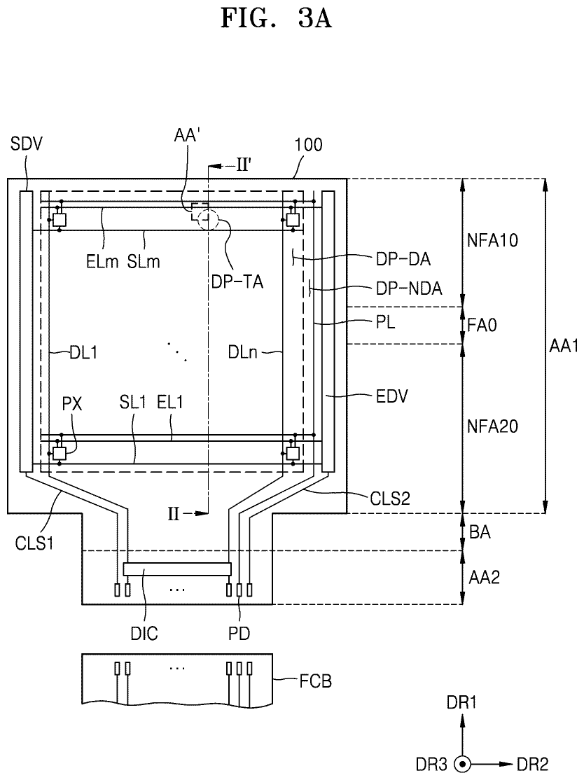

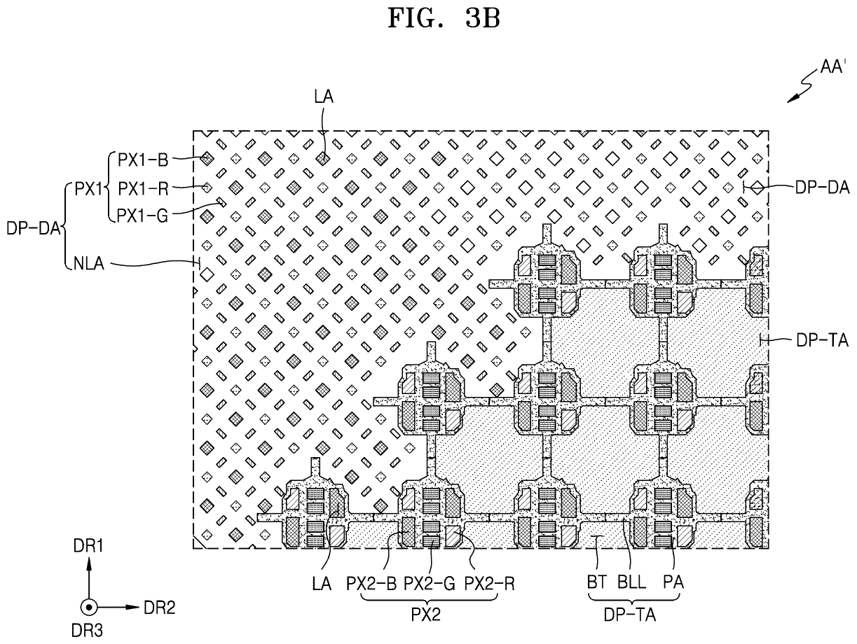

FIG. 3A is a plan view of a display panel according to an embodiment. FIG. 3B is a plan view of a partial area of the display panel according to an embodiment. FIG. 3B is an enlarged plan view of a partial area AA′ of FIG. 3A.

Referring to FIG. 3A, a display panel DP may include a display area DP-DA and a non-display area DP-NDA around the display area DP-DA. The display area DP-DA and the non-display area DP-NDA may be distinguished by presence of a pixel PX, e.g., belonging to a plurality of pixels PX. The pixel PX may be disposed in the display area DP-DA. A scan driver SDV, a data driver, and an emission driver EDV may be disposed in the non-display area DP-NDA. The data driver may be a partial circuit configured in the driving chip DIC illustrated in FIG. 3A.

The display panel DP may include a first area AA1, a second area AA2, and a bending area BA which are disposed in a first direction DR1. The second area AA2 and the bending area BA may be a partial area of the non-display area DP-NDA. The bending area BA may be disposed between the first area AA1 and the second area AA2.

The first area AA1 may be an area corresponding to the display surface DS of FIG. 1A. The first area AA1 may include a first non-folding area NFA10, a second non-folding area NFA20, and a folding area FA0. The first non-folding area NFA10, the second non-folding area NFA20, and the folding area FA0 may correspond to the first non-folding area NFA1, the second non-folding area NFA2, and the folding area FA of FIGS. 1A to 1C, respectively, of FIGS. 1 to 1C.

The lengths of each of the bending area BA and the second area AA2 in the first direction DR1 may be shorter than the length of the first area AA1 in the first direction DR1. An area having a shorter length in a bending axis direction may be bent more easily.

The display panel DP may include a plurality of pixels PX, a plurality of scan lines SL1 to SLm, a plurality of data lines DL1 to DLn, a plurality of light-emitting lines EL1 to ELm, a first control line CSL1 and a second control line CSL2, a power line PL, and a plurality of pads PD. Here, each of m and n is a positive integer. The pixels PX may be connected to the scan lines SL1 to SLm, the data lines DL1 to DLn, and the light-emitting lines EL1 to ELm.

The scan lines SL1 to SLm may extend in the second direction DR2 to be connected to the scan driver SDV. The data lines DL1 to DLn may extend in the first direction DR1 and may pass through the bending area BA to be connected to the driving chip DIC. The light-emitting lines EL1 to ELm may extend in the second direction DR2 to be connected to the emission driver EDV.

The power line PL may include a portion extending in the second direction DR2 and a portion extending in the first direction DR1. The portion extending in the first direction DR1 and the portion extending in the second direction DR2 may be disposed in different layers. The portion of the power line PL extending in the first direction DR1 may pass through the bending area BA and extend to the second area AA2. The power line PL may provide a first voltage to the pixels PX.

The first control line CLS1 may be connected to the scan driver SDV, and may pass through the bending area BA and extend toward a lower end of the second area AA2. The second control line CLS2 may be connected to the emission driver EDV, and may pass through the bending area BA and extend toward the lower end of the second area AA2.

The pads PD may be disposed adjacent to the lower end of the second area AA2 on a plane. The driving chip DIC, the power line PL, the first control line CLS1, and the second control line CLS2 may be connected to the pads PD. A flexible circuit board FCB may be electrically connected to the pads PD through an anisotropic conductive adhesive layer.

Referring to FIG. 3B, a sensing area DP-TA may be an area having a higher light transmittance and lower resolution than the display area DP-DA. The light transmittance and resolution may be measured within a reference area. The sensing area DP-TA may include a light blocking structure having a less occupancy ratio than the display area DP-DA, within the reference area. The light blocking structure may include a conductive pattern of a circuit layer, an electrode of a light-emitting device, a light blocking pattern, and the like, which are described below.

The sensing area DP-TA may have a lower resolution than the display area DP-DA, within the reference area. The sensing area DP-TA may have a smaller number of pixels disposed therein than the display area DP-DA, within the reference area (or the same area).

As illustrated in FIG. 3B, a first pixel PX1 may be disposed in the display area DP-DA, and a second pixel PX2 may be disposed in the sensing area DP-TA. The first pixel PX1 and the second pixel PX2 may have different light-emitting areas when comparing areas of pixels of the same color. The first pixel PX1 and the second pixel PX2 may have different arrangements.

FIG. 3B illustrates that light-emitting areas LA of the first pixel PX1 and the second pixel PX2 represent the first pixel PX1 and the second pixel PX2. Each of the light-emitting areas LA may be defined as an area in which an anode of a light-emitting device is exposed from a pixel defining layer. Within the display area DP-DA, a non-light-emitting area NLA may be disposed between the light-emitting areas LA.

The first pixel PX1 may include a first color pixel PX1-R, a second color pixel PX1-G, and a third color pixel PX1-B, and the second pixel PX2 may include a first color pixel PX2-R, a second color pixel PX2-G, and a third color pixel PX2-B. Each of the first pixel PX1 and the second pixel PX2 may include a red pixel, a green pixel, and a blue pixel.

The sensing area DP-TA may include a pixel area PA, a line area BLL, and a transmission area BT. The second pixel PX2 may be disposed within the pixel area PA. Two first color pixels PX2-R, four second color pixels PX2-G, and two third color pixels PX2-B may be disposed within one pixel area PA, but the present disclosure is not limited thereto.

A conductive pattern, a signal line, or a light blocking pattern related to the second pixel PX2 may be disposed in the pixel area PA and the line area BLL. The light blocking pattern may be a metal pattern, and may substantially overlap the pixel area PA and the line area BLL. The pixel area PA and the line area BLL may be non-transmission areas.

The transmission area BT may be an area through which an optical signal substantially passes. The second pixel PX2 may not be disposed in the transmission area BT, and thus, a conductive pattern, a signal line, or a light blocking pattern may be disposed. Accordingly, the transmission area BT may increase a light transmittance of the sensing area DP-TA.

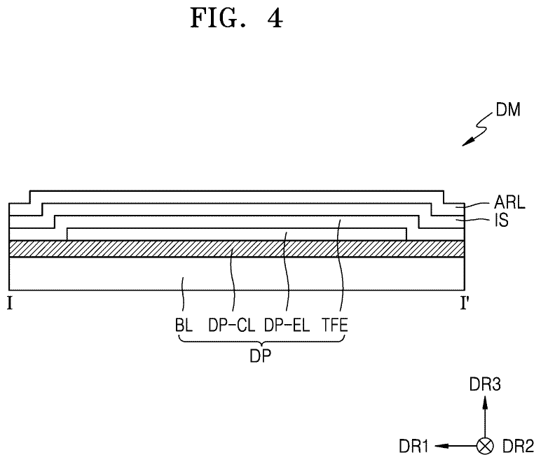

FIG. 4 is a cross-sectional view of a display module according to an embodiment, e.g., a cross-sectional view of an example of a display module taken along line I-I′ of FIG. 2A.

Referring to FIG. 4, a display module DM may include a display panel DP, an input sensor IS, and an anti-reflection layer ARL. The display panel DP may include a base layer BL, a circuit layer DP-CL, a light-emitting device layer DP-EL, and an encapsulation layer TFE.

The base layer BL may provide a base surface on which the circuit layer DP-CL is disposed. The base layer BL may be a flexible substrate that may be bent, folded, rolled, or the like. The base layer BL may be, for example, a glass substrate, a metal substrate, or a polymer substrate. However, the present disclosure is not limited thereto, and the base layer BL may be, for example, an inorganic layer, an organic layer, or a composite material layer according to embodiments.

The base layer BL may have a multi-layer structure. For example, the base layer BL may include a first synthetic resin layer, a multi-layer or single-layer inorganic layer, and a second synthetic resin layer disposed on the multi-layer or single-layer inorganic layer. Each of the first synthetic resin layer and the second synthetic resin layer may include a polyimide-based resin, but is not particularly limited thereto.

The circuit layer DP-CL may be disposed on the base layer BL. The circuit layer DP-CL may include, for example, an insulating layer, a semiconductor pattern, a conductive pattern, a signal line, and the like.

The light-emitting device layer DP-EL may be disposed on the circuit layer DP-CL. The light-emitting device layer DP-EL may include a light-emitting device. For example, the light-emitting device may include an organic light-emitting material, an inorganic light-emitting material, an organic-inorganic light-emitting material, a quantum dot, a quantum rod, a micro LED, or a nano LED.

The encapsulation layer TFE may be disposed on the light-emitting device layer DP-EL. The encapsulation layer TFE may protect the light-emitting device layer DP-EL from foreign substances such as, for example, moisture, oxygen, and dust particles. The encapsulation layer TFE may include at least one inorganic layer. The encapsulation layer TFE may include a stack structure of an inorganic layer, an organic layer, and an inorganic layer.

The input sensor IS may be directly disposed on the display panel DP. The display panel DP and the input sensor IS may be formed through a continuous process. Here, the expression “being directly disposed” may indicate that a third component is not disposed between the input sensor IS and the display panel DP. For example, in an embodiment in which the input sensor IS is directly disposed on the display panel DP, a separate adhesive layer is not disposed between the input sensor IS and the display panel DP.

The anti-reflection layer ARL may be directly disposed on the input sensor IS. The anti-reflection layer ARL may reduce a reflectance of external light incident from the outside of the display device DD. The anti-reflection layer ARL may include color filters. The color filters may have a certain arrangement. For example, the color filters may be disposed by considering light-emitting colors of pixels included in the display panel DP. In some embodiments, the anti-reflection layer ARL may further include a black matrix adjacent to the color filters.

In an embodiment, locations of the input sensor IS and the anti-reflection layer ARL may be interchanged. In an embodiment, the anti-reflection layer ARL may be replaced with a polarizing film. The polarizing film may be bonded to the input sensor IS through an adhesive layer.

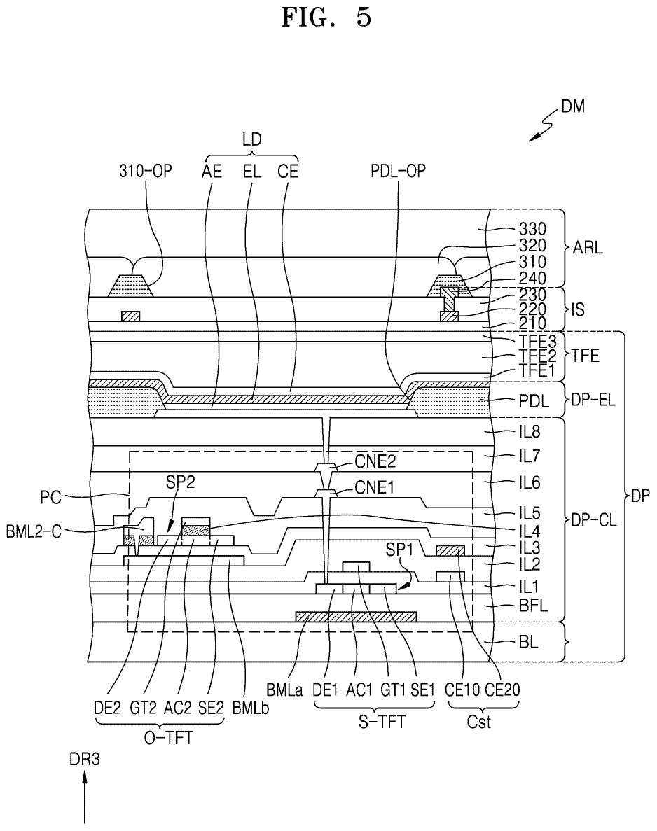

FIG. 5 is a cross-sectional view of a portion of a display module according to an embodiment. FIG. 5 illustrates a portion of the display module DM of an embodiment illustrated in FIG. 4 in more detail. In some embodiments, FIG. 5 illustrates components of the display module DM, which correspond to one pixel.

FIG. 5 illustrates one light-emitting device LD, and a silicon transistor S-TFT and an oxide transistor O-TFT of a pixel circuit PC. At least one of a plurality of transistors included in the pixel circuit PC may be the oxide transistor O-TFT, and the remaining transistors may be the silicon transistor S-TFT.

A buffer layer BFL may be disposed on a base layer BL. The buffer layer BFL may prevent metal atoms or impurities from being diffused from the base layer BL to a first semiconductor pattern SP1 on the buffer layer BFL. The first semiconductor pattern SP1 may include an active area AC1 of the silicon transistor S-TFT. The buffer layer BFL may adjust a supply rate of heat during a crystallization process for forming the first semiconductor pattern SP1 so that the first semiconductor pattern SP1 is uniformly formed.

A first back metal layer BMLa may be disposed below the silicon transistor S-TFT, and a second back metal layer BMLb may be disposed below the oxide transistor O-TFT. The first back metal layer BMLa and the second back metal layer BMLb may overlap the pixel circuit PC. The first back metal layer BMLa and the second back metal layer BMLb may block external light from reaching the pixel circuit PC.

The first back metal layer BMLa may be disposed to correspond to at least a partial area of the pixel circuit PC. The first back metal layer BMLa may overlap a driving transistor implemented as the silicon transistor S-TFT.

The first back metal layer BMLa may be disposed between the base layer BL and the buffer layer BFL. In an embodiment, an inorganic barrier layer may be further disposed between the first back metal layer BMLa and the buffer layer BFL. The first back metal layer BMLa may be connected to an electrode or a line and may receive a constant voltage or a signal from the electrode or the line. According to an embodiment, the first back metal layer BMLa may be a floating electrode isolated from another electrode or another line.

The second back metal layer BMLb may be disposed below the oxide transistor O-TFT to correspond to the oxide transistor O-TFT. The second back metal layer BMLb may be disposed between a second insulating layer IL2 and a third insulating layer IL3. The second back metal layer BMLb may be in a same layer as a second electrode CE20 of a storage capacitor Cst. The second back metal layer BMLb may be connected to a contact electrode BML2-C to receive a constant voltage or a signal. The contact electrode BML2-C may be in a same layer as a gate GT2 of the oxide transistor O-TFT.

Each of the first back metal layer BMLa and the second back metal layer BMLb may include a reflective metal. For example, each of the first back metal layer BMLa and the second back metal layer BMLb may include sliver (Ag), an alloy including silver (Ag), molybdenum (Mo), an alloy including molybdenum (Mo), aluminum (Al), an alloy including aluminum (Al), aluminum nitride (AlN), tungsten (W), tungsten nitride (WN), copper (Cu), p+-doped amorphous silicon, and the like. The first back metal layer BMLa and the second back metal layer BMLb may include the same material or different materials.

According to an embodiment, the second back metal layer BMLb may be omitted. The first back metal layer BMLa may extend to below the oxide transistor O-TFT so that the first back metal layer BMLa may block light incident below the oxide transistor O-TFT.

The first semiconductor pattern SP1 may be disposed on the buffer layer BFL. The first semiconductor pattern SP1 may include a silicon semiconductor. For example, the silicon semiconductor may include amorphous silicon, polycrystalline silicon, or the like. For example, the first semiconductor pattern SP1 may include low-temperature polysilicon.

FIG. 5 illustrates only a portion of the first semiconductor pattern SP1 disposed on the buffer layer BFL, and it is to be understood that the first semiconductor pattern SP1 may be further disposed in another area. The first semiconductor pattern SP1 may be disposed in a particular rule across pixels. The first semiconductor pattern SP1 may have different electrical characteristics according to whether the first semiconductor pattern SP1 is doped. The first semiconductor pattern SP1 may include a first area having high conductivity and a second area having low conductivity. The first area may be doped with an N-type dopant or a P-type dopant. A P-type transistor may include a doping area doped with a P-type dopant, and an N-type transistor may include a doping area doped with an N-type dopant. The second area may be an undoped area or an area doped at a lower concentration than the first area.

Conductivity of the first area may be greater than conductivity of the second area, and the first area may substantially operate as an electrode or a signal line. The second area may substantially correspond to an active area (or a channel) of a transistor. In some embodiments, a portion of the first semiconductor pattern SP1 may be an active area of a transistor, another portion of the first semiconductor pattern SP1 may be a source or a drain of the transistor, and another portion of the first semiconductor pattern SP1 may be a connection electrode or a connection signal line.

A source area SE1 (or a source), the active area AC1 (or the channel), and a drain area DE1 (or a drain) of the silicon transistor S-TFT may be formed from the first semiconductor pattern SP1. The source area SE1 and the drain area DE1 may extend from the active area AC1 in opposite directions in a cross-section.

The first insulating layer IL1 may be disposed on the buffer layer BFL. The first insulating layer IL1 may overlap a plurality of pixels in common and cover the first semiconductor pattern SP1. The first insulating layer IL1 may be an inorganic layer and/or an organic layer and may have a single-layer or multi-layer structure. The first insulating layer IL1 may include at least one of, for example, aluminum oxide, titanium oxide, silicon oxide, silicon nitride, silicon oxynitride, zirconium oxide, and hafnium oxide. In an embodiment, the first insulating layer IL1 may be a single-layered silicon oxide layer. An insulating layer of the circuit layer DP-CL described below as well as the first insulating layer IL1 may be an inorganic layer and/or an organic layer and may have a single-layer or multi-layer structure. The inorganic layer may include at least one of the materials described above, but is not limited thereto.

A gate GT1 of the silicon transistor S-TFT may be disposed on the first insulating layer IL1. The gate GT1 may be a portion of a metal pattern. The gate GT1 may overlap the active area AC1. In a process of doping the first semiconductor pattern SP1, the gate GT1 may function as a mask. The gate GT1 may include, for example, titanium (Ti), silver (Ag), an alloy including silver (Ag), molybdenum (Mo), an alloy including molybdenum (Mo), aluminum (Al), an alloy including aluminum (Al), aluminum nitride (AlN), tungsten (W), tungsten nitride (WN), copper (Cu), indium tin oxide (ITO), indium zinc oxide (IZO), and the like, but is not particularly limited thereto.

The second insulating layer IL2 may be disposed on the first insulating layer IL1 and may cover the gate GT1. The third insulating layer IL3 may be disposed on the second insulating layer IL2. The second electrode CE20 of the storage capacitor Cst may be disposed between the second insulating layer IL2 and the third insulating layer IL3. In some embodiments, a first electrode CE10 of the storage capacitor Cst may be disposed between the first insulating layer IL1 and the second insulating layer IL2.

A second semiconductor pattern SP2 may be disposed on the third insulating layer IL3. The second semiconductor pattern SP2 may include an active area AC2 of the oxide transistor O-TFT described below. The second semiconductor pattern SP2 may include oxide semiconductor. The second semiconductor pattern SP2 may include transparent conductive oxide (TCO) such as, for example, indium tin oxide (ITO), indium zinc oxide (IZO), indium gallium zinc oxide (IGZO), zinc oxide (ZnO), or indium oxide (In₂O₃).

The oxide semiconductor may include a plurality of areas distinguished according to whether the transparent conductive oxide is reduced. An area in which transparent conductive oxide is reduced (hereinafter, a reduction area) may have greater conductivity than an area in which transparent conductive oxide is not reduced (hereinafter, a non-reduction area). The reduction area may substantially operate as a source and/or a drain or a signal line of a transistor. The non-reduction area may substantially correspond to a semiconductor area (or an active area or a channel) of the transistor. In some embodiments, a partial area of the second semiconductor pattern SP2 may be a semiconductor area of a transistor, another partial area of the second semiconductor pattern SP2 may be a source area and/or a drain area of the transistor, and another portion of the second semiconductor pattern SP2 may be a signal transmission area.

A source area SE2 (or a source), the active area AC2 (or the channel), and a drain area DE2 (or a drain) of the oxide transistor O-TFT may be formed from the second semiconductor pattern SP2. The source area SE2 and the drain area DE2 may extend from the active area AC2 in opposite directions in the cross-section.

A fourth insulating layer IL4 may be disposed above the third insulating layer IL3. As illustrated in FIG. 5, the fourth insulating layer IL4 may be an insulating pattern that overlaps the gate GT2 of the oxide transistor O-TFT and exposes the source area SE2 and the drain area DE2 of the oxide transistor O-TFT. As illustrated in FIG. 5, the fourth insulating layer IL4 may cover the second semiconductor pattern SP2.

As illustrated in FIG. 5, the gate GT2 of the oxide transistor O-TFT may be disposed on the fourth insulating layer IL4. The gate GT2 of the oxide transistor O-TFT may be a portion of a metal pattern. The gate GT2 of the oxide transistor O-TFT may overlap the active area AC2.

A fifth insulating layer IL5 may be disposed on the fourth insulating layer IL4 and may cover the gate GT2. A first connection electrode CNE1 may be disposed on the fifth insulating layer IL5. The first connection electrode CNE1 may be connected to the drain area DE1 of the silicon transistor S-TFT through a contact hole passing through the first insulating layer IL1, the second insulating layer IL2, the third insulating layer IL3, the fourth insulating layer IL4, and the fifth insulating layer IL5.

A sixth insulating layer IL6 may be disposed on the fifth insulating layer IL5. A second connection electrode CNE2 may be disposed on the sixth insulating layer IL6. The second connection electrode CNE2 may be connected to the first connection electrode CNE1 through a contact hole passing through the sixth insulating layer IL6. A seventh insulating layer IL7 may be disposed on the sixth insulating layer IL6 and may cover the second connection electrode CNE2. An eighth insulating layer IL8 may be disposed on the seventh insulating layer IL7.

Each of the sixth insulating layer IL6, the seventh insulating layer IL7, and the eighth insulating layer IL8 may be an organic layer. For example, each of the sixth insulating layer IL6, the seventh insulating layer IL7, and the eighth insulating layer IL8 may include general-purpose polymer such as benzocyclobutene (BCB), polyimide, hexamethyldisiloxane (HMDSO), polymethylmethacrylate (PMMA), or polystyrene (PS), a polymer derivative having a phenolic group, acrylic polymer, imide-based polymer, arylether-based polymer, amide-based polymer, fluorine-based polymer, p-xylene-based polymer, vinyl alcohol-based polymer, and a blend thereof.

The light-emitting device LD may include a first electrode AE, a light-emitting layer EL, and a second electrode CE. The second electrode CE may be commonly provided on a plurality of light-emitting devices.

The first electrode AE of the light-emitting device LD may be disposed above the eighth insulating layer IL8. The first electrode AE of the light-emitting device LD may be a (semi-)light-transmissive electrode or a reflective electrode. According to an embodiment, each of the first electrodes AE of the light-emitting device LD may include a reflective layer including, for example, Ag, Mg, Al, Pt, Pd, Au, Ni, Nd, Ir, Cr, or a compound thereof, and a transparent or translucent electrode layer formed on the reflective layer. The transparent or translucent electrode layer may include at least one of, for example, indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the first electrode AE of the light-emitting device LD may include a stack structure of ITO, Ag, and ITO.

A pixel defining layer PDL may be disposed on the eighth insulating layer IL8. The pixel defining layer PDL may have a light-absorbing property, e.g., the pixel defining layer PDL may have a black color. The pixel defining layer PDL may include a black coloring agent. The black coloring agent may include a black dye and a black pigment. The black coloring agent may include carbon black, metal such as chromium, or oxide thereof. The pixel defining layer PDL may correspond to a light blocking pattern having light blocking characteristics.

The pixel defining layer PDL may cover a portion of the first electrode AE of the light-emitting device LD. For example, an opening PDL-OP exposing a portion of the first electrode AE of the light-emitting device LD may be defined in the pixel defining layer PDL. The pixel defining layer PDL may increase a distance between an edge of the first electrode AE and the second electrode CE of the light-emitting device LD. Therefore, the pixel defining layer PDL may prevent an arc or the like from occurring at the edge of the first electrode AE.

In an embodiment, a hole control layer may be disposed between the first electrode AE and the light-emitting layer EL. The hole control layer may include a hole transport layer and may further include a hole injection layer. An electronic control layer may be disposed between the light-emitting layer EL and the second electrode CE. The electron control layer may include an electron transport layer and may further include an electron injection layer. The hole control layer and the electronic control layer may be commonly formed in a plurality of pixels PX (refer to FIG. 3A) by using an open mask.

An encapsulation layer TFE may be disposed on the light-emitting device layer DP-EL. The encapsulation layer TFE may include an inorganic layer TFE1, an organic layer TFE2, and an inorganic layer TFE3 which are sequentially stacked, but layers constituting the encapsulation layer TFE are not limited thereto.

The inorganic layers TFE1 and TFE3 may protect the light-emitting device layer DP-EL from moisture and oxygen, and the organic layer TFE2 may protect the light-emitting device layer DP-EL from foreign substances such as dust particles. The inorganic layers TFE1 and TFE3 may include, for example, a silicon nitride layer, a silicon oxynitride layer, a silicon oxide layer, a titanium oxide layer, or an aluminum oxide layer. The organic layer TFE2 may include an acrylic organic layer, but is not limited thereto.

An input sensor IS may be disposed on the display panel DP. The input sensor IS may be referred to as a sensor, an input detection layer, or an input detection panel. The input sensor IS may include a sensor base layer 210, a first conductive layer 220, a detection insulating layer 230, and a second conductive layer 240.

The sensor base layer 210 may be directly disposed on the display panel DP. The sensor base layer 210 may be an inorganic layer including at least one of silicon nitride, silicon oxynitride, and silicon oxide. In some embodiments, the sensor base layer 210 may be an organic layer including, for example, an epoxy resin, an acrylic resin, or an imide-based resin. The sensor base layer 210 may have a single-layer structure, or a multi-layer structure stacked in the third direction DR3.

Each of the first conductive layer 220 and the second conductive layer 240 may have a single-layer structure, or a multi-layer structure stacked in the third direction DR3. The first conductive layer 220 and the second conductive layer 240 may include conductive lines defining mesh-shaped detection electrodes. In an embodiment, the conductive lines do not overlap the opening PDL-OP and overlap the pixel defining layer PDL.

A conductive layer having a single-layer structure may include a metal layer or a transparent conductive layer. The metal layer may include, for example, molybdenum, silver, titanium, copper, aluminum, or an alloy thereof. The transparent conductive layer may include transparent conductive oxide, such as, for example, indium tin oxide (ITO), indium zinc oxide (IZO), zinc oxide (ZnO), or indium zinc tin oxide (IZTO). In some embodiments, the transparent conductive layer may include conductive polymer such as, for example, PEDOT, metal nanowires, graphene, or the like.

A conductive layer having a multi-layer structure may include metal layers sequentially stacked. The metal layers may have, for example, a three-layer structure of titanium, aluminum, and titanium. The conductive layer having the multi-layer structure may include at least one metal layer and at least one transparent conductive layer.

The detection insulating layer 230 may be disposed between the first conductive layer 220 and the second conductive layer 240. The detection insulating layer 230 may include an inorganic layer. The inorganic layer may include at least one of, for example, aluminum oxide, titanium oxide, silicon oxide, silicon nitride, silicon oxynitride, zirconium oxide, and hafnium oxide.

In some embodiments, the detection insulating layer 230 may include an organic layer. The organic layer may include at least one of, for example, an acrylic resin, a methacrylic resin, polyisoprene, a vinyl resin, an epoxy resin, a urethane resin, a cellulose resin, a siloxane resin, a polyimide resin, a polyamide resin, and a perylene resin.

An anti-reflection layer ARL may be disposed on the input sensor IS. The anti-reflection layer ARL may include a division layer 310, a plurality of color filters 320, and a planarization layer 330.

A material constituting the division layer 310 may include any material that may absorb light. The division layer 310 may be a layer having a black color, and in an embodiment, the division layer 310 may include a black coloring agent. The black coloring agent may include a black dye and a black pigment. The black coloring agent may include carbon black, metal such as chromium, or an oxide thereof.

The division layer 310 may cover the second conductive layer 240 of the input sensor IS. The division layer 310 may prevent reflection of external light by the second conductive layer 240. In some areas of the display module DM, the division layer 310 may be omitted. An area in which the division layer 310 is omitted and is not disposed may have a higher transmittance than another area.

An opening 310-OP may be defined in the division layer 310. The opening 310-OP may overlap the first electrode AE of the light-emitting device LD. Any one of the plurality of color filters 320 may overlap the first electrode AE of the light-emitting device LD. Any one of the plurality of color filters 320 may cover the opening 310-OP. Each of the plurality of color filters 320 may contact the division layer 310.

The planarization layer 330 may cover the division layer 310 and the plurality of color filters 320. The planarization layer 330 may include an organic material and may provide a planarization surface on an upper surface of the planarization layer 330. In an embodiment, the p lanarization layer 330 may be omitted.

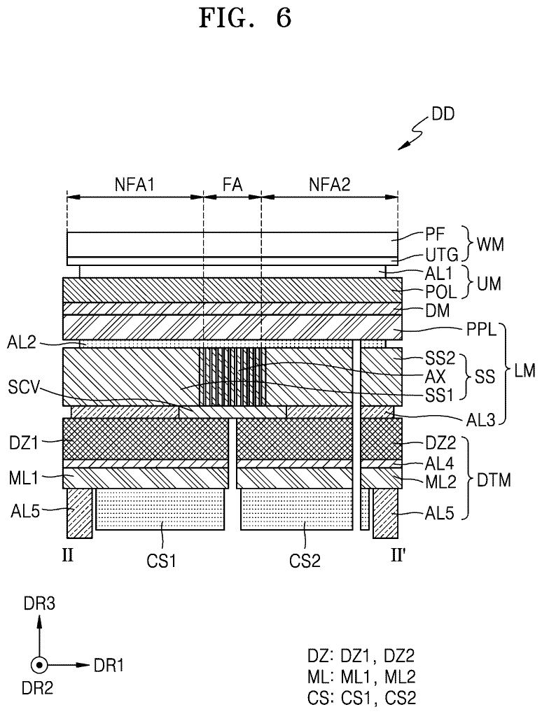

FIG. 6 is a side view of an example of a display device taken along line II-II′ of FIG. 3A.

Referring to FIG. 6, a display device DD according to an embodiment may include a window WM, an upper member UM, a display module DM, a lower member LM, and a digitizer module DTM. The upper member UM may refer to a component disposed between the window WM and the display module DM, the lower member LM may refer to a component disposed between the display module DM and the digitizer module DTM, and the digitizer module DTM may refer to a component disposed below the lower member LM.

In some embodiments, the display device DD may include a window protective layer PF, a thin film glass substrate UTG, a first adhesive layer AL1, a polarization member POL, the display module DM, a lower protective film PPL, a second adhesive layer AL2, a panel support SS, a third adhesive layer AL3, a digitizer DZ, a fourth adhesive layer AL4, a metal layer ML, a cushion member CS, and a fifth adhesive layer AL5. According to embodiments, on the basis of one component, one side in a third direction DR3 may be expressed as an upper portion and the other side in the third direction DR3 may be expressed as a lower portion.

In some embodiments, the display device DD may include the display module DM including a first non-folding area NFA1, a second non-folding area NFA2, a folding area FA disposed between the first non-folding area NFA1 and the second non-folding area NFA2, the lower member LM disposed below the display module DM, and the digitizer module DTM disposed below the lower member LM.

The lower member LM may include the panel support SS including a first panel support SS1, an auxetic structure AX, and a second panel support SS2 that are sequentially disposed in a first direction DR1. The first panel support SS1 may overlap the first non-folding area NFA1, the second panel support SS2 may overlap the second non-folding area NFA2, and the auxetic structure AX may overlap the folding area FA.

The panel support SS may also be referred to as a display panel support. According to embodiments, the panel support SS may refer to a structural support member disposed beneath the display module DM, and may include the first panel support SS1, the auxetic structure AX, and the second panel support SS2 arranged in a linear direction in the first direction DR1, as described above. The panel support SS may be formed of rigid or semi-rigid materials and may provide mechanical support during folding and unfolding operations.

In some embodiments, the first non-folding area NFA1, the folding area FA, and the second non-folding area NFA2 of the display device DD may be equally applied to the display device DD, e.g., the window protective layer PF, the thin film glass substrate UTG, the first adhesive layer AL1, the display module DM, the lower protective film PPL, the second adhesive layer AL2, the panel support SS, the third adhesive layer AL3, the digitizer DZ, the fourth adhesive layer AL4, a metal layer ML, and the cushion member CS which are described above. For example, a portion of the display module DM, which overlaps the first non-folding area NFA1 of the display device DD in the third direction DR3, may be a first polarization portion of the display module DM, a portion of the display module DM, which overlaps the folding area FA of the display device DD in the third direction DR3, may be a first bending portion of the display module DM, and a portion of the display module DM, which overlaps the second non-folding area NFA2 of the display device DD, may be a second polarization portion of the display module DM.

In some embodiments, a first display area DA1, a first non-display area NDA1, a second display area DA2, and a second non-display area NDA2 of the display device DD may be equally applied to the window protective layer PF, the thin film glass substrate UTG, the first adhesive layer AL1, the display module DM, the lower protective film PPL, the second adhesive layer AL2, the panel support SS, the third adhesive layer AL3, the digitizer DZ, the metal layer ML, and the cushion member CS which are described above.

The window protective layer PF may perform at least one of functions including, for example, scattering prevention, shock absorption, scratch prevention, fingerprint prevention, and glare prevention of the thin film glass substrate UTG described below. The window protective layer PF may be disposed on one side surface (hereinafter, referred to as an upper surface) of the thin film glass substrate UTG in the third direction DR3. The window protective layer PF may be attached to the upper surface of the thin film glass substrate UTG through an adhesive member such as a pressure sensitive adhesive.

The thin film glass substrate UTG may protect the display module DM, which is described further below, from, for example, external impact, environmental exposure, or contamination. The thin film glass substrate UTG may be disposed on one side surface (hereinafter, referred to as an upper surface) of the polarization member POL in the third direction DR3. The thin film glass substrate UTG may include a transparent material and may include, for example, glass or plastic. For example, the thin-film glass substrate (UTG) may be ultra thin glass having a thickness of about 0.1 mm or less or a transparent polyimide film.

The thin film glass substrate UTG may be attached to the upper surface of the polarization member POL by the first adhesive layer AL1. The first adhesive layer AL1 may be a transparent adhesive film or a transparent adhesive resin.

The polarization member POL may polarize light emitted from the display module DM or may polarize light incident on the display module DM. The polarization member POL may be disposed on one side surface (hereinafter, referred to as an upper surface) of the display module DM in the third direction DR3.

The polarization member POL may be omitted according to an embodiment. In a case in which the polarization member POL is omitted, the thin film glass substrate UTG may be attached to the upper surface of the display module DM by the first adhesive layer AL1.

The display module DM may include a display panel including a screen on which an image is displayed. The display module DM may include, for example, an organic light-emitting display module DM including an organic light-emitting layer, a micro LED display module DM using a micro LED, a quantum dot light-emitting display module DM using a quantum dot LED including a quantum dot light-emitting layer, or an inorganic light-emitting display module DM using an inorganic light-emitting device including inorganic semiconductor. Referring to FIGS. 1A to 1C, the display module DM may include a display panel that displays an image on one side in the third direction DR3.

The lower protective film PPL may support the display module DM and protect a lower surface of the display module DM. The lower protective film PPL may be disposed on the other side surface (hereinafter, referred to as a lower surface) of the display module DM in the third direction DR3. The lower protective film PPL may include plastic such as, for example, polyethylene terephthalate or polyimide.

The panel support SS may support the lower surface of the display module DM. The panel support SS may be disposed on the other side surface (hereinafter, referred to as a lower surface) of the lower protective film PPL in the third direction DR3. The panel support SS may be a rigid member having a shape or volume that is not easily changed by pressure from external impact. A thickness of the panel support SS may be, for example, about 30 μm to about 200 μm.

The panel support SS may include the first panel support SS1 overlapping the first non-folding area NFA1 in the third direction DR3, the second panel support SS2 overlapping the second non-folding area NFA2 in the third direction DR3, and the auxetic structure AX overlapping the folding area FA in the third direction DR3 and disposed between the first panel support SS1 and the second panel support SS2.

In an embodiment, by disposing the auxetic structure AX between the first panel support SS1 and the second panel support SS2, the panel support SS may provide a hybrid configuration that transitions from rigid regions to a flexible folding region in a single, integrated layer. This configuration may enable the first and second panel supports SS1 and SS2 to maintain structural rigidity in the first and second non-folding areas NFA1 and NFA2, while the auxetic structure AX disposed in the folding area FA may accommodate mechanical deformation during folding. This sequential arrangement may allow for a smoother distribution of strain along the first direction DR1, suppress abrupt stress concentration at the interface between rigid and flexible regions, and help preserve the structural integrity of the display device DD over repeated folding and unfolding operations.

A cover layer SCV may be disposed on the other side surface (hereinafter, referred to as a lower surface) of the panel support SS in the third direction DR3. In some embodiments, the cover layer SCV may be disposed in an area of the lower surface of the panel support SS that overlaps the folding area FA in the third direction DR3. The cover layer SCV may include a material having elasticity, which may vary in a length according to folding and unfold operations of the display device DD.

The cover layer SCV may include a polymer material having hyper elastic characteristics. For example, the cover layer SCV may include temperature polyurethane (TPU) having elasticity. The cover layer SCV may have a thickness of about 1 μm to about 20 μm.

In some embodiments, the cover layer SCV may have a small modulus to correspond to the folding and unfolding operations of the display device DD. For example, the cover layer SCV may include a material having a modulus of less than about 1 Gpa.

The cover layer SCV may prevent ingress of foreign substances into the panel support SS.

The third adhesive layer AL3 may be disposed on the lower surface of the panel support SS. In some embodiments, the third adhesive layer AL3 may be disposed in an area of the lower surface of the panel support SS other than an area in which the cover layer SCV is disposed. The third adhesive layer AL3 may fill a space between the panel support SS and the digitizer DZ, which may increase or maximize a bonding area between the panel support SS and the digitizer DZ and may physically fix the panel support SS and the digitizer DZ.

The third adhesive layer AL3 may include a pressure sensitive adhesive. In a case in which an adhesive member includes a pressure sensitive adhesive, when pressure is applied to the adhesive member, an adhesive force of the adhesive member to the panel support SS and/or the digitizer DZ may be increased. For example, after the third adhesive layer AL3 including the pressure sensitive adhesive is disposed between the panel support SS and the digitizer DZ, pressure may be applied to adhere the panel support SS and the digitizer DZ through the adhesive member.

The pressure sensitive adhesive included in the third adhesive layer AL3 may include, for example, a natural rubber adhesive, a styrene/butadiene latex-based adhesive, an ABA block copolymer type thermoplastic rubber (wherein A is a thermoplastic polystyrene end block and B is a middle block of a polyisoprene rubber, a polybutadiene rubber, a polyethylene rubber, or a polybutylene rubber), a butyl rubber, an acrylic polymer adhesive such as polyisobutylene, polyacrylate, vinyl acetate/acrylic ester copolymer, and a vinyl ether polymer adhesive such as polyvinyl methyl ether, polyvinyl ethyl ether, and polyvinyl isobutyl ether.

The third adhesive layer AL3 may have a thickness of about 15 μm or less. For example, the thickness of the third adhesive layer AL3 may be about 10 μm, but is not limited thereto.

The digitizer DZ may include a first digitizer DZ1 and a second digitizer DZ2. The first digitizer DZ1 and the second digitizer DZ2 may be disposed on the lower surface of the panel support SS. As described above, the first digitizer DZ1 and the second digitizer DZ2 may be attached to the lower surface of the panel support SS by the third adhesive layer AL3.

In an embodiment, the first digitizer DZ1 and the second digitizer DZ2 are not disposed in an entirety of the folding area FA. For example, the first digitizer DZ1 and the second digitizer DZ2 may partially overlap the folding area FA with a gap interposed therebetween (e.g., at least a portion of the folding area FA corresponding to the location of the gap does not overlap the first digitizer DZ1 and the second digitizer DZ2). For example, at least a portion of the folding area FA may exist in which the first digitizer DZ1 and the second digitizer DZ2 are not disposed. As a result, folding stress of the display device DD may be reduced. The first digitizer DZ1 may overlap the first non-folding area NFA1, and the second digitizer DZ2 may overlap the second non-folding area NFA2. The gap between the first digitizer DZ1 and the second digitizer DZ2 may overlap the folding area FA and may be smaller than a width of the folding area FA in the first direction DR1.

The first digitizer DZ1 and the second digitizer DZ2 may include electrode patterns that detect approach or contact of an electronic pen, such as a stylus pen supporting an electromagnetic induction method. The first digitizer DZ1 and the second digitizer DZ2 may detect a magnetic field or electromagnetic signal emitted from the electronic pen on the basis of the electrode patterns and determine, as touch coordinates, a point at which the detected magnetic field or electromagnetic signal is the greatest.

Magnetic metal powder may be disposed on a lower surface of the first digitizer DZ1 and a lower surface of the second digitizer DZ2. In some embodiments, the magnetic field or electromagnetic signal passing through the first digitizer DZ1 and the second digitizer DZ2 may flow into the magnetic metal powder. Therefore, due to the magnetic metal powder, the magnetic field or electromagnetic signal from the first digitizer DZ1 and the second digitizer DZ2 may be reduced from being emitted to the lower surface of the display device DD.

The fourth adhesive layer AL4 may be disposed on a lower surface of the digitizer DZ. In some embodiments, the fourth adhesive layer AL4 may be disposed on the lower surface of the first digitizer DZ1 and the lower surface of the second digitizer DZ2 to cover the lower surface of the first digitizer DZ1 and the lower surface of the second digitizer DZ2. The fourth adhesive layer AL4 may fill a space between the digitizer DZ and the metal layer ML to increase or maximize a bonding area between the digitizer DZ and the metal layer ML and may physically fix the digitizer DZ and the metal layer ML.

The fourth adhesive layer AL4 may include substantially the same material as the third adhesive layer AL3 described above. Therefore, a description thereof is omitted.

The fourth adhesive layer AL4 may have a thickness of about 15 μm or less. For example, the third adhesive layer AL3 may have a thickness of about 13 μm, but is not limited thereto.

The metal layer ML may support the digitizer DZ. The metal layer ML may include a first metal layer ML1 and a second metal layer ML2. The first metal layer ML1 may be disposed on the other side surface (hereinafter, referred to as the lower surface) of the first digitizer DZ1 in the third direction DR3, and the second metal layer ML2 may be disposed on the other side surface (hereinafter, referred to as the lower surface) of the second digitizer DZ2 in the third direction DR3.

In an embodiment, the first metal layer ML1 and the second metal layer ML2 are not disposed in an entirety of the folding area FA. For example, the first metal layer ML1 and the second metal layer ML2 may partially overlap the folding area FA with a gap interposed therebetween (e.g., at least a portion of the folding area FA corresponding to the location of the gap does not overlap the first metal layer ML1 and the second metal layer ML2). For example, at least a portion of the folding area FA may exist in which the first metal layer ML1 and the second metal layer ML2 are not disposed. As a result, the folding stress of the display device DD may be reduced. In some embodiments, the first metal layer ML1 may overlap the first non-folding area NFA1, and the second metal layer ML2 may overlap the second non-folding area NFA2. A gap between the first metal layer ML1 and the second metal layer ML2 may overlap the folding area FA and may be smaller than the width of the folding area FA in the first direction DR1. In an embodiment, the size of the gap between the first metal layer ML1 and the second metal layer ML2 may be about the same as the size of the gap between the first digitizer DZ1 and the second digitizer DZ2.

The first metal layer ML1 and the second metal layer ML2 may include a material having high rigidity. For example, the first metal layer ML1 and the second metal layer ML2 may include stainless steel or copper (Cu) such as SUS316.

The cushion member CS may include a first cushion member CS1 and a second cushion member CS2. The first cushion member CS1 and the second cushion member CS2 may absorb external shock ad may prevent the panel support SS and the digitizer DZ from being damaged. The first cushion member CS1 and the second cushion member CS2 may include a material having elasticity, such as, for example, a rubber, a urethane-based material, or a sponge formed by foaming an acrylic-based material.

The first cushion member CS1 may be disposed on a lower surface of the first metal layer ML1, and the second cushion member CS2 may be disposed on a lower surface of the second metal layer ML2. In an embodiment, the first cushion member CS1 and the second cushion member CS2 are not disposed in an entirety of the folding area FA. For example, the first cushion member CS1 and the second cushion member CS2 may partially overlap the folding area FA with a gap interposed therebetween (e.g., at least a portion of the folding area FA corresponding to the location of the gap does not overlap the first cushion member CS1 and the second cushion member CS2). For example, at least a portion of the folding area FA may exist in which the first cushion member CS1 and the second cushion member cS2 are not disposed. As a result, the folding stress of the display device DD may be reduced. The first cushion member CS1 may be disposed in the first non-folding area NFA1, and the second cushion member CS2 may be disposed in the second non-folding area NFA2. A gap between the first cushion member CS1 and the second cushion member CS2 may overlap the folding area FA and may be smaller than the width of the folding area FA in the first direction DR1. In an embodiment, the size of the gap between the first cushion member CS1 and the second cushion member CS2 may be larger than the size of each of the gap between the first metal layer ML1 and the second metal layer ML2 and the gap between the first digitizer DZ1 and the second digitizer DZ2.

The fifth adhesive layer AL5 may prevent moisture or dust from permeating into the display device DD. The fifth adhesive layer AL5 may be disposed on the other surface (hereinafter, referred to as the lower surface) of the first metal layer ML1 in the third direction DR3 and the other surface (hereinafter, referred to as the lower surface) of the second metal layer ML2 in the third direction DR3. The fifth adhesive layer AL5 may be disposed at an edge of the first metal layer ML1 and an edge of the second metal layer ML2. The fifth adhesive layer AL5 may surround the first cushion member CS1 and the second cushion member CS2. The fifth adhesive layer AL5 may include a waterproof tape or a waterproof member that attaches the lower surface of the first metal layer ML1 to an upper surface of a frame disposed on the lower surface of the cushion member CS.

In some embodiments, the fifth adhesive layer AL5 does not surround the first cushion member CS1 and the second cushion member CS2 and may overlap, in the third direction DR3, a magnet that maintains a second state of the display device DD. In some embodiments, to prevent the digitizer DZ or the display module DM from being affected by magnetism of the magnet, the fifth adhesive layer AL5 may operate as a magnetism shielding member capable of shielding magnetism.

An auxetic pattern structure may refer to a material or structure having a negative Poissons ratio. The Poissons ratio refers to a physical characteristic that indicates the degree to which a material shrinks or stretches in a vertical direction when the material is stretched or compressed.

For example, according to embodiments, in the case of the auxetic structure AX, this lateral expansion or contraction behavior may enable the auxetic structure AX to conform more dynamically to bending forces applied during folding of the display device DD. When the folding area FA undergoes compressive or tensile stress during bending, the auxetic structure AX may expand or contract in a direction perpendicular to the fold, which may reduce localized strain and mitigate the risk of material fatigue or delamination. This adaptive deformation behavior may contribute to an improved fold profile and extend the mechanical lifespan of the device.

In some embodiments, unlike a normal material having a positive Poissons ratio that shrinks in the vertical direction in a case in which the material is stretched in one direction, the auxetic pattern structure is a material that expands or compresses in the vertical direction accordingly in a case in which the material is stretched or compressed in one direction.

The characteristic of the auxetic pattern structure may indicate that, when the auxetic pattern structure is deformed by an external force, the auxetic pattern structure may have improved or superior elongation and restoration characteristics and uniformly expands or shrinks to absorb more energy and thus may be used as a shock absorbing material or the like.

The degree to which the foldable display device DD is folded and then bent and deformed may be evaluated through a crease, and the crease may be reduced with a low height of the crease. For example, embodiments may provide a crease that is less visible to the user.

By applying the auxetic pattern structure to the panel support SS, a thickness of the crease may be reduced compared to an existing lattice structure, and a repulsive force may be reduced when folding.

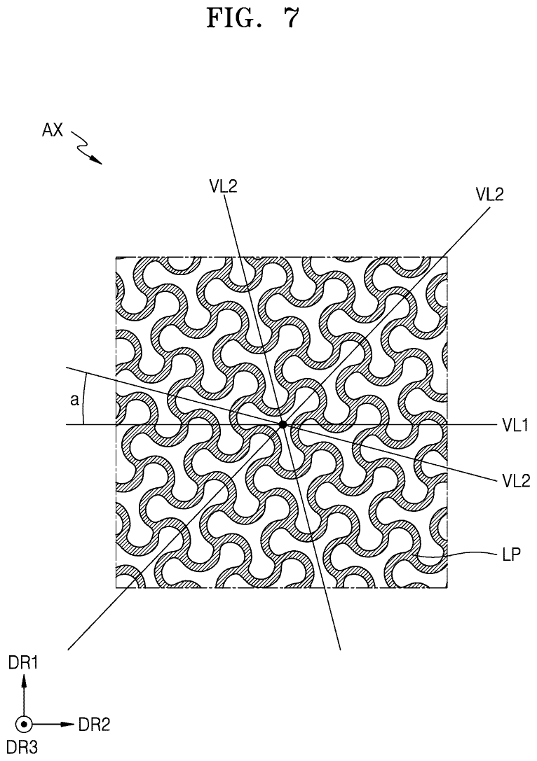

According to embodiments, the ability of the auxetic structure AX to reduce crease thickness and repulsive force during folding may be influenced not only by the negative Poisson's ratio but also by the specific geometry and orientation of its unit pattern UC (refer to FIG. 7). For example, when the unit pattern UC is inclined at a non-zero angle relative to the folding axis FX, the auxetic response may be directionally improved to provide higher deformation capacity in the folding area FA. This tailored orientation may improve the ability of the auxetic structure AX to accommodate bending strain while preserving layer alignment across the fold, which may help to reduce crease visibility and improve tactile smoothness of the display surface after repeated folding.

Hereinafter, the auxetic structure AX, which is disposed between the first panel support SS1 and the second panel support SS2 of the panel support SS, overlaps the folding area FA, and has the auxetic pattern structure, will be described in detail.

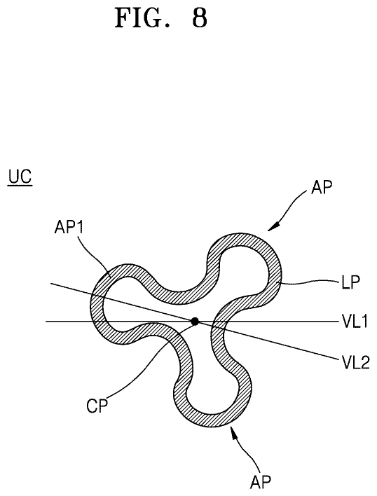

FIG. 7 is a plan view schematically illustrating an auxetic structure according to an embodiment. FIG. 8 is a plan view schematically illustrating one unit pattern of FIG. 7.

An auxetic structure AX having the same unit pattern UC may also have a different negative Poissons ratio according to which direction the auxetic structure AX is folded in. In some embodiments, the unit pattern UC of the auxetic structure AX having the same thickness, line width, pitch, and pattern shape may also have a different negative Poissons ratio according to a folding direction.

As the negative Poissons ratio approaches 0, a height of a crease, which is a height difference between a folded area and a non-folded area caused by the display device DD being folded, may decrease.

In an embodiment, when the unit pattern UC is rotated relative to the folding axis FX, the principal direction of auxetic expansion or contraction may align more closely with the direction of applied folding stress. This alignment may allow the pattern to better accommodate the strain field generated during folding and unfolding, contributing to lower crease height and improved elastic recovery. As such, the orientation of the unit pattern UC within the auxetic structure AX may provide a tunable design parameter that can be adjusted based on product-specific folding profiles or hinge geometries.

As the height of the crease decreases, a user may not easily recognize a difference in the height of the crease when using the display device DD. That is, as the height of the crease decreases, the crease may become less visible to the user. As a result, visibility may be improved.

In some embodiments, a modulus value may be derived that reduces the height of a crease in the display device DD including the unit pattern UC of the auxetic structure AX, even when factors such as, for example, the thickness, line width, pitch, pattern shape, and negative Poisson's ratio are not changed.

In some embodiments, the height of the crease may be influenced by both the modulus and the negative Poisson's ratio, and thus, a combination of a suitable modulus and a small negative Poisson's ratio may be selected to achieve a display device DD having a low crease height.

In some embodiments, by rotating the same auxetic pattern structure having the same thickness, line width, pitch, and pattern shape, a crease height may be reduced by applying the rotated auxetic pattern structure having an absolute value of the smallest negative Poissons ratio when the display device DD is folded. The crease height may be reduced by selecting a modulus value suitable for the deformation characteristics of the same auxetic pattern structure. Even when a particular auxetic pattern structure is selected, further reduction in crease height may be achieved by adjusting the rotation angle at which the auxetic pattern structure is disposed in the folding area.

The combination of a low modulus and a negative Poisson's ratio near zero, as implemented in embodiments of the present disclosure, may allow the auxetic structure AX to deform more uniformly when folded, thereby suppressing localized stress concentrations that could otherwise lead to microcracking or layer delamination. Additionally, a low modulus may facilitate smoother bending, while the auxetic expansion may mitigate vertical displacement at the crease, leading to reduced visibility of the crease and improved user experience.

Still referring to FIGS. 7 and 8, the auxetic structure AX may include a plurality of unit patterns UC that are repeated. When defining a first virtual line VL1 parallel to the folding axis FX of the folding area FA extending in the second direction DR2 perpendicular to the first direction DR1, the unit pattern UC may be asymmetrical with respect to the first virtual line VL1 passing through a central point CP of the unit pattern UC. For example, in an embodiment, the auxetic structure AX may include a plurality of unit patterns UC that are repeated to form a continuous pattern. The first virtual line VL1 may be defined parallel to the folding axis FX of the folding area FA, which extends in the second direction DR2 perpendicular to the first direction DR1. The unit pattern UC may be asymmetrical with respect to the first virtual line VL1, which passes through a central point CP of the unit pattern UC.

A second virtual line VL2 passing through the central point CP of the unit pattern UC may be defined so that the unit pattern UC is vertically symmetrical. One second virtual line VL2 or a plurality of second virtual lines VL2 may be provided according to the unit pattern UC. An angle a formed between the second virtual line VL2 and the first virtual line VL1 may be an acute angle. For example, in an embodiment, the second virtual line VL2 may be defined to pass through the central point CP of the unit pattern UC such that the unit pattern UC is symmetrical with respect to the second virtual line VL2. One or more second virtual lines VL2 may be defined for each unit pattern UC. An angle a formed between the second virtual line VL2 and the first virtual line VL1 may be an acute angle.

The auxetic structure AX may have the negative Poissons ratio, and the angle a formed between the second virtual line VL2 and the first virtual line VL1 may be the acute angle, e.g., may be about 0° to about 30°. The negative Poissons ratio of the auxetic structure AX including an auxetic pattern rotated at a certain angle may be, for example, about −0.3 to about 0.

The plurality of unit patterns UC may be defined by a line pattern LP. The line pattern LP may have a certain thickness to define the plurality of unit patterns UP, and the plurality of unit patterns UC may form the auxetic structure AX.

The auxetic structure AX may be configured to provide sufficient rigidity to protect the display device DD from external shock, while also maintaining enough flexibility to enable folding and unfolding of the display device DD. A material of the auxetic structure AX, a modulus of the auxetic structure AX, a thickness of the line pattern LP, and a pitch of the unit pattern UC may be determined and adjusted to satisfy conditions as described above.

For example, in applications where a tighter fold radius is desired, a lower modulus material and a smaller pitch between adjacent unit patterns UC may be selected to allow greater deformation without fracture. Conversely, in use cases prioritizing structural durability or higher impact resistance, a higher modulus material and larger pattern pitch may be utilized. These design variables may provide flexibility in tailoring the auxetic structure AX to different product specifications, e.g., focusing on minimal crease, extended lifecycle, resistance to mechanical stress, etc., based on the application.

In some embodiments, the auxetic structure AX may include at least one of, for example, stainless steel, copper, titanium, aluminum, and high-density polyethylene (HDPE). The modulus of the auxetic structure AX may be, for example, about 10 MPa to about 1 GPa. The line pattern LP may have a thickness of about 30 μm to about 100 μm. A plurality of unit patterns UC along the second virtual line VL2 may have a pitch of about 450 μm to about 2,000 μm.

Hereinafter, the auxetic structure AX including an auxetic pattern structure, according to an embodiment of the present disclosure, is described in further detail.

The unit pattern UC of the auxetic structure AX may include arms AP spaced apart from one another at about the same angle and extending from the central point CP of the unit pattern UC. For example, three arms AP may be provided.

An end of the arm AP may be convex on the basis of the central point CP of the unit pattern UC, and a waist of the arm AP between the end of the arm AP and the central point CP of the unit pattern UC may be concave. The end of the arm AP, which is convex in one unit pattern UC, may be a waist of an arm AP which is concave in another adjacent unit pattern UC.

As shown in FIG. 8, in an embodiment, each arm AP may extend outward from the central point CP of the unit pattern UC and may include a concave waist region (e.g., a narrowed waist region) located between the central point CP and a convex distal end. The curvature of the concave waist may facilitate localized deformation, while the convex end may serve as an interlocking interface with the adjacent unit pattern UC. In the repeated arrangement of unit patterns UC, the convex end of an arm AP in one unit pattern UC may be aligned with and partially received by the concave waist of an arm AP from a neighboring unit pattern UC. This geometric configuration may contribute to a continuous, repeating auxetic pattern capable of controlled expansion and contraction during folding or unfolding of the display device DD.

Straight lines along center lines of respective arms AP from the central point CP of the unit pattern UC may be the second virtual lines VL2, respectively. In a case in which three arms AP are provided, three second virtual lines VL2 may be provided.

When folding the display device DD having the unit pattern UC including the arm AP, the auxetic structure AX may be disposed by rotating the unit pattern UC so that the negative Poissons ratio approaches 0.

The arm AP may include a first arm AP1 having the smallest angle between an extension line from the central point CP of the unit pattern UC to the arm AP, for example, a straight line along the center line of the arm AP from the central point CP of the unit pattern UC, and the first virtual line VL1.

In some embodiments, the angle a between the second virtual line VL2 connecting the first arm AP1 and the central point CP of the unit pattern UC and the first virtual line VL1 may be about 0° to about 30°. In the unit pattern UC of FIG. 8 according to an embodiment, the angle a between the second virtual line VL2 connecting the first arm AP1 and the central point CP of the unit pattern UC and the first virtual line VL1 may be about 5° to about 20°. For example, in an embodiment, the angle a may be about 7° to about 15°. However, a value of the angle a between the second virtual line VL2 and the first virtual line VL1, which is for having a negative Poissons ratio close to 0 in a unit pattern other than the unit pattern UC of FIG. 8, may be changed.

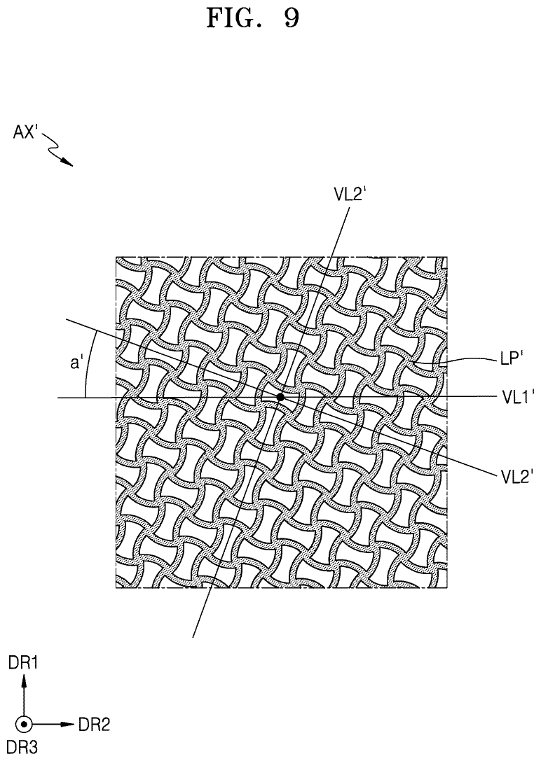

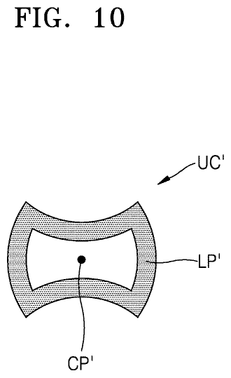

FIG. 9 is a plan view schematically illustrating an auxetic structure according to an embodiment. FIG. 10 is a plan view schematically illustrating one unit pattern of FIG. 9.

Referring to FIGS. 9 and 10, an auxetic structure AX′ may include a plurality of unit patterns UC′ that are repeated.

Both ends of a unit pattern UC′ in a longitudinal direction may be convex, and a waist portion between the both ends may have a concave shape. A convex end in one unit pattern UC′ may be a concave waist in another adjacent unit pattern UC′.

In an embodiment, the geometry of unit pattern UC′ may differ from the unit pattern UC of FIG. 8 in terms of the curvature profile and angular spacing between adjacent arms. These differences may influence how the auxetic structure AX′ expands or contracts under deformation. For example, the transition between the convex end and the concave waist in UC′ may result in a more uniform deformation gradient across the pattern, which may further reduce stress concentration at the crease when the display device DD is folded.

Straight lines connecting a central point CP′ of the unit pattern UC′ to central points of both ends of the unit pattern UC′ or central points of both waists of the unit pattern UC′ may be second virtual lines VL2′, respectively. The unit pattern UC′ may have two second virtual lines VL2′.

When folding the display device DD including the auxetic structure AX′ having the unit pattern UC′, the auxetic structure AX′ may be disposed by rotating the unit pattern UC′ so that a negative Poissons ratio approaches 0.

In an embodiment according to FIG. 9, the rotation of the unit pattern UC′ may allow the deformation axes of the concave and convex portions to align more effectively with the primary folding direction, which may improve symmetry and reduce residual strain. For example, the structure of FIG. 9 may exhibit twofold directional behavior, enabling a different range of design tunability in response to folding mechanics.

When defining a first virtual line VL1′ parallel to the folding axis FX of the folding area FA extending in the second direction DR2 perpendicular to the first direction DR1, the unit pattern UC′ may be asymmetric with respect to the first virtual line VL1′ passing through the central point CP′ of the unit pattern UC′.

An angle a′ formed between the second virtual line VL2′ and the first virtual line VL1′ defined to pass through the central point CP′ of the unit pattern UC′ so that the unit pattern UC′ is vertically symmetrical may be an acute angle.

A plurality of unit patterns UC′ may be defined by a line pattern LP′. The line pattern LP′ may have a certain thickness to define the plurality of unit patterns UC′, and the plurality of unit patterns UC′ may form the auxetic structure AX′.

The auxetic structure AX′ may be configured to provide sufficient rigidity to protect the display device DD from external shock, while also maintaining enough flexibility to enable folding and unfolding of the display device DD. The material of the auxetic structure AX′, its modulus, the thickness of the line pattern LP′, and the pitch of the unit pattern UC′ may be selected and adjusted to meet mechanical performance requirements for foldable applications.

For example, where a tighter folding radius is desired, a unit pattern UC′ with increased curvature or reduced pitch may be combined with a lower modulus material, which may improve flexibility. Conversely, in applications concerned with structural support and long-term durability, a less curved unit pattern with higher pitch and modulus values may be selected. These parameters may be adjusted based on the desired mechanical profile of the foldable device, allowing the auxetic structure AX′ to serve in a range of product configurations.

Aspects of the description of the auxetic structure AX′ with reference to FIGS. 9 and 10 may apply to the description of the auxetic structure AX′ with reference to FIGS. 7 and 8.

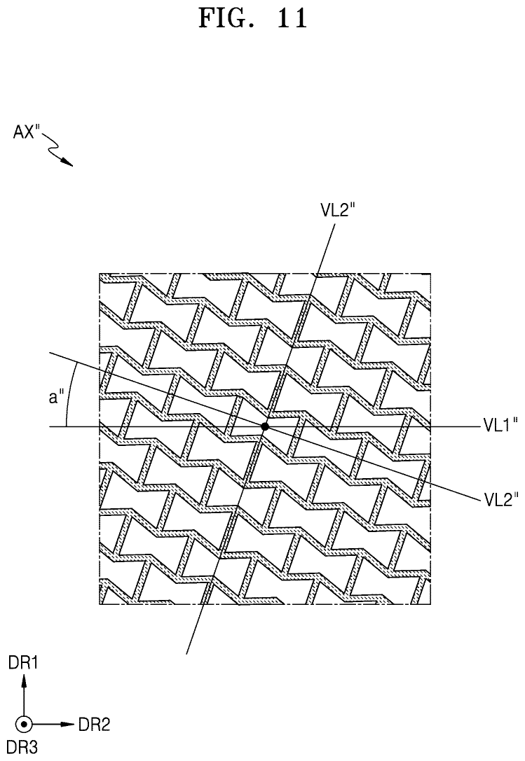

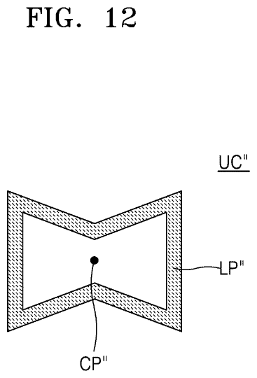

FIG. 11 is a plan view schematically illustrating an auxetic structure according to an embodiment. FIG. 12 is a plan view schematically illustrating one unit pattern of FIG. 11.

Referring to FIGS. 11 and 12, an auxetic structure AX″ of another example may include a plurality of unit patterns UC″ that are repeated.

The unit pattern UC″ may have an hourglass shape. In some embodiments, the unit pattern UC″ may have a shape in which shorter sides from among parallel sides of two trapezoids are in contact with each other. A central point CP″ of the unit pattern UC″ may be located at the center of the shorter sides from among the parallel sides of the trapezoids.

A straight line passing through the central point CP″ of the unit pattern UC″ and centers of two longer sides from among the parallel sides of the trapezoids and an extension line of the shorter sides of the parallel sides of the trapezoids may become second virtual lines VL2″, respectively. The unit pattern UC″ may have two second virtual lines VL2″.

When folding the display device DD including the auxetic structure AX″ having the unit pattern UC″, the auxetic structure AX″ may be disposed by rotating the unit pattern UC″ so that the most negative Poissons ratio approaches 0.

When defining a first virtual line VL1″ parallel to the folding axis FX of the folding area FA extending in the second direction DR2 perpendicular to the first direction DR1, the unit pattern UC″ may be asymmetric with respect to the first virtual line VL1″ passing through the central point CP″ of the unit pattern UC″.

An angle a″ between the second virtual line VL2″ and the first virtual line VL1″ defined to pass through the central point CP″ of the unit pattern UC″ so that the unit pattern UC″ is vertically symmetrical may be an acute angle.

A plurality of unit patterns UC″ may be defined by a line pattern LP″. The line pattern LP″ may have a certain thickness to define the plurality of unit patterns UC″, and the plurality of unit patterns UC″ may form the auxetic structure AX″.

The auxetic structure AX″ may be configured to provide sufficient rigidity to protect the display device DD from external shock, while also offering enough flexibility to enable folding and unfolding of the display device DD. The material of the auxetic structure AX″, its modulus, the thickness of the line pattern LP″, and the pitch of the unit pattern UC″ may be selected and adjusted to meet the mechanical performance requirements described above.

Aspects of the description of the auxetic structure AX″ with reference to FIGS. 11 and 12 may apply to the description of the auxetic structure AX with reference to FIGS. 7 and 8.

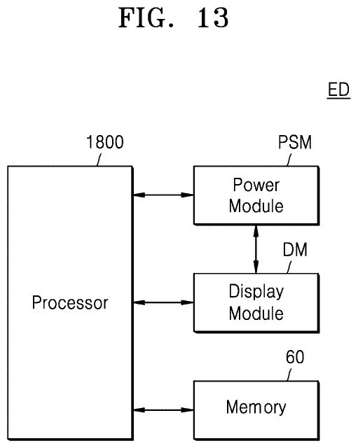

FIG. 13 is a block diagram of an electronic device according to an embodiment.

Referring to FIG. 13, an electronic device ED according to an embodiment may include a display module DM, a processor 1800, a memory 60, and a power module PSM.

The processor 1800 may include, for example, at least one of a central processing unit (CPU), an application processor (AP), a graphic processing unit (GPU), a communication processor (CP), an image signal processor (ISP), and a controller.

The memory 60 may store data information used for an operation of the processor 1800 or the display module DM. In a case in which the processor 1800 executes an application stored in the memory 60, an image data signal and/or an input control signal may be transmitted to the display module DM, and the display module DM may process the received signal and output image information through a display screen.

The power module PSM may include a power supply module such as, for example, a power adapter or a battery device, and a power conversion module that converts power supplied by the power supply module to generate power used for an operation of the electronic device ED.

At least one of the respective components of the electronic device ED described above may be included within the display device DD according to embodiments described above. In some embodiments, some of individual modules functionally included within one module may be included within a display device, while others may be provided separately from the display device. For example, the display device DD may include the display module DM, and the processor 1800, the memory 60, and the power module PSM may be provided in the form of other devices within the electronic device ED rather than the display device DD.

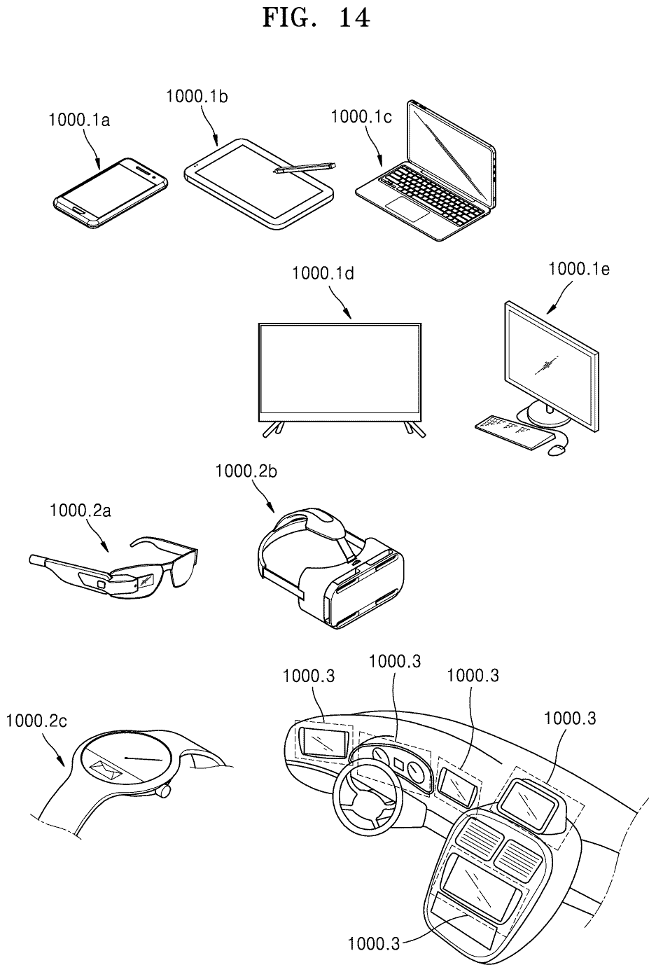

FIG. 14 is a view schematically illustrating various types of electronic devices according to various embodiments.

Referring to FIG. 14, various types of electronic devices to which the display device DD according to the embodiments is applied may include an electronic device for image display, such as, for example, a smartphone 1000.1a, a tablet PC 1000.1b, a laptop 1000.1c, a TV 1000.1d, or a computer monitor 1000.1e, a wearable electronic device including a display module, such as smart glasses 1000.2a, a head-mounted display 1000.2b, or a smart watch 1000.2c, a vehicle electronic device 1000.3 including a display module such as a center information display (CID) or a room mirror display disposed on an instrument panel, a center fascia, or a dashboard of a vehicle, and the like.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

According to embodiments, an auxetic form having a negative Poissons ratio may be disposed in a folding area to implement a display device having improved shock absorption and tensile resilience in the folding area and an electronic device including the same.

However, the effects obtainable by the disclosure are not limited to the effects described above, and other technical effects not mentioned may be clearly understood by those skilled in the art from the description of the disclosure described below.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a display module comprising a first non-folding area, a second non-folding area, and a folding area disposed between the first non-folding area and the second non-folding area; and
a panel support comprising a first panel support, an auxetic structure, and a second panel support disposed below the display module and sequentially disposed in a first direction,
whereinthe first panel support overlaps the first non-folding area, the second panel support overlaps the second non-folding area, and the auxetic structure overlaps the folding area,
wherein the auxetic structure comprises a unit pattern provided repeatedly and in a plurality, the unit pattern is asymmetrical with respect to a first virtual line passing through a central point of the unit pattern, and the first virtual line is parallel to a folding axis of the folding area extending in a second direction perpendicular to the first direction.

2. The display device of claim 1, wherein an angle formed between a second virtual line and the first virtual line passing through the central point of the unit pattern is an acute angle, and the unit pattern is vertically symmetrical.

3. The display device of claim 1, wherein the auxetic structure has a negative Poissons ratio.

4. The display device of claim 3, wherein the negative Poissons ratio of the auxetic structure is about −0.3 to about 0.

5. The display device of claim 1, further comprising:
a line pattern defining the plurality of unit patterns.

6. The display device of claim 5, wherein the line pattern has a thickness of about 30 μm to about 100 μm.

7. The display device of claim 1, wherein the auxetic structure comprises at least one of stainless steel, copper, titanium, aluminum, and high-density polyethylene (HDPE).

8. The display device of claim 2, wherein the plurality of unit patterns disposed along the second virtual line has a pitch of about 450 μm to about 2,000 μm.

9. The display device of claim 1, wherein the auxetic structure has a modulus of about 10 MPa to about 1 GPa.

10. The display device of claim 1, wherein the unit pattern comprises a plurality of arms spaced apart from one another at a same angle and extending from the central point of the unit pattern.

11. The display device of claim 10, wherein the plurality of arms comprises three arms.

12. The display device of claim 11, wherein an end of one of the arms is convex with respect to the central point of the unit pattern, and a waist of the one of the arms between the end of the one of the arms and the central point of the unit pattern is concave.

13. The display device of claim 11, wherein one of the arms has a smallest angle between an extension line from the central point of the unit pattern to the one of the arms and the first virtual line, and an angle between a second virtual line connecting the one of the arms to the central point of the unit pattern and the first virtual line is about 30° or less.

14. The display device of claim 1, wherein the panel support has a thickness of about 30 μm to about 200 μm.

15. The display device of claim 1, wherein the display module provides a display surface, the display surface provides a flat surface in a first mode of the display device, and at least a portion of the display surface provides a curved surface on a basis of a reference axis extending in the second direction in a second mode.

16. A display device, comprising:
a display module comprising a first non-folding area, a second non-folding area, and a folding area disposed between the first non-folding area and the second non-folding area; and
a panel support comprising a first panel support, an auxetic structure, and a second panel support disposed below the display module and sequentially disposed in a first direction,
wherein the first panel support overlaps the first non-folding area, the second panel support overlaps the second non-folding area, and the auxetic structure overlaps the folding area,
wherein the auxetic structure comprises a unit pattern provided repeatedly and in a plurality, and the unit pattern comprises three arms spaced apart from one another at a same angle and extending from a central point of the unit pattern,
wherein the unit pattern is asymmetrical with respect to a first virtual line passing through the central point of the unit pattern, and the first virtual line is parallel to a folding axis of the folding area extending in a second direction perpendicular to the first direction.

17. The display device of claim 16, wherein an end of one of the arms is convex with respect to the central point of the unit pattern, and a waist of the one of the arms between the end of the one of the arms and the central point of the unit pattern is concave.

18. The display device of claim 16, wherein one of the arms has a smallest angle between an extension line from the central point of the unit pattern to the one of the arms and the first virtual line, and an angle between a second virtual line connecting the one of the arms to the central point of the unit pattern and the first virtual line is about 30° or less.

19. The display device of claim 16, further comprising a line pattern defining the plurality of unit patterns, wherein the line pattern has a thickness of about 30 μm to about 100 μm.

20. An electronic device comprising a display device, wherein the display device comprises:
a display module comprising a first non-folding area, a second non-folding area, and a folding area disposed between the first non-folding area and the second non-folding area; and
a panel support comprising a first panel support, an auxetic structure, and a second panel support disposed below the display module and sequentially disposed in a first direction,
wherein the first panel support overlaps the first non-folding area, the second panel support overlaps the second non-folding area, and the auxetic structure overlaps the folding area,
wherein the auxetic structure comprises a plurality of repeated unit patterns, the unit pattern is asymmetrical with respect to a first virtual line passing through a central point of the unit pattern, and the first virtual line is parallel to a folding axis of the folding area extending in a second direction perpendicular to the first direction.
